(19) United States
(12) Patent Application Publication
(10) Pub. No.: US 2023/0110126 A1
(43) Pub. Date: Apr. 13, 2023

(54) SEMICONDUCTOR PACKAGES HAVING A PACKAGE SUBSTRATE AND METHOD FOR MANUFACTURING THE SAME

(71) Applicant: SAMSUNG ELECTRONICS CO., LTD, SUWON-SI (KR)

(72) Inventors: JEONGHYUN LEE, Seoul (KR); DONGWOOK KIM, ASAN-SI (KR); HYUNGLAK MA, ASAN-SI (KR); JIYONG PARK, HWASEONG-SI (KR); HWANPIL PARK, HWASEONG-SI (KR)

(21) Appl. No.: 17/804,104

(22) Filed: May 26, 2022

(30) Foreign Application Priority Data
Oct. 8, 2021 (KR) 10-2021-0134454

(51) Int. Cl. H01L 23/498; H01L 25/16; H01L 23/00

(52) U.S. Cl. CPC H01L 23/49838; H01L 25/16; H01L 24/16; H01L 24/32; H01L 24/73; H01L 23/49816; H01L 23/49822; H01L 2924/1438; H01L 2924/1431; H01L 2924/1432; H01L 2224/16227; H01L 2224/16237; H01L 2224/32225; H01L 2224/73204; H01L 2224/1601

(57) ABSTRACT

A semiconductor package includes a package substrate that includes a substrate base and a lower solder resist layer that covers a lower surface of the substrate base, where the lower solder resist layer includes a ponding recess that extends from a lower surface toward an upper surface of the lower solder resist layer, a semiconductor chip attached to an upper surface of the package substrate, an auxiliary chip attached to a lower surface of the package substrate adjacent to the ponding recess through a plurality of chip terminals, where the auxiliary chip includes a first side and a second side opposite to each other in a plane, and an underfill layer that fills a space between the package substrate and the auxiliary chip, surrounds the plurality of chip terminals, and fills the ponding recess.

### CROSS-REFERENCE TO RELATED APPLICATION

This application claims priority under 35 U.S.C. § 119 from Korean Patent Application No. 10-2021-0134454, filed on Oct. 8, 2021 in the Korean Intellectual Property Office, the contents of which are herein incorporated by reference in their entirety.

### TECHNICAL FIELD

Embodiments of the inventive concept are directed to a semiconductor package, and more particularly, to a semiconductor package that has a package substrate to which a semiconductor chip is attached.

### Discussion of the Related Art

To easily mount a semiconductor chip in an electronic product, a semiconductor package is provided in which a semiconductor chip is attached to a package substrate, and optionally, in addition to a semiconductor chip, various types of auxiliary chips or unit device chips such as passive elements and active elements may be further attached to the semiconductor package.

### SUMMARY

Embodiments of the inventive concept provide a semiconductor package that has a connection reliability of an auxiliary chip or a unit device chip attached to a package substrate.

According to an embodiment of the inventive concept, there is provided a semiconductor package that includes a package substrate that includes a substrate base and a lower solder resist layer that covers a lower surface of the substrate base, where the lower solder resist layer includes a ponding recess that extends from a lower surface toward an upper surface of the lower solder resist layer; a semiconductor chip attached to an upper surface of the package substrate; an auxiliary chip attached to a lower surface of the package substrate adjacent to the ponding recess through a plurality of chip terminals, where the auxiliary chip includes a first side and a second side opposite to each other in a plane; and an underfill layer that fills a space between the package substrate and the auxiliary chip, surrounds the plurality of chip terminals, and fills the ponding recess. The ponding recess is arranged asymmetrically with respect to the auxiliary chip in a plane.

According to another embodiment of the inventive concept, there is provided a semiconductor package that includes: a package substrate that includes a substrate base, a plurality of upper chip connection pads placed on an upper surface of the substrate base, a plurality of lower connection pads and a plurality of auxiliary chip connection pads placed on a lower surface of the substrate base, and a lower solder resist layer that covers the lower surface of the substrate base and does not cover the plurality of lower connection pads and the plurality of auxiliary chip connection pads, where the lower solder resist layer includes a ponding recess that extends from the lower surface toward the upper surface of the lower solder resist layer; a plurality of chip connection members attached to the plurality of upper chip connection pads; a main semiconductor chip attached to the plurality of chip connection members; an auxiliary chip attached to the lower surface of the package substrate adjacent to the ponding recess through a plurality of chip terminals attached to the plurality of auxiliary chip connection pads, wherein the auxiliary chip includes first and second sides opposite to each other in a plane; a plurality of external connection terminals attached to the plurality of lower connection pads; and an underfill layer that fills a space between the package substrate and the auxiliary chip, surrounds the plurality of chip terminals, and fills the ponding recess. The ponding recess is arranged asymmetrically with respect to the auxiliary chip in a first horizontal direction perpendicular to the first side of the auxiliary chip.

According to another embodiment of the inventive concept, there is provided a semiconductor package that includes: a package substrate that includes a substrate base, a plurality of upper chip connection pads placed on an upper surface of the substrate base, a plurality of lower connection pads and a plurality of auxiliary chip connection pads placed on a lower surface of the substrate base, and a lower solder resist layer that covers the lower surface of the substrate base and does not cover the plurality of lower connection pads and the plurality of auxiliary chip connection pads, where the lower solder resist layer includes a ponding recess that extends from the lower surface toward the upper surface of the lower solder resist layer; a plurality of chip connection members attached to the plurality of upper chip connection pads; a main semiconductor chip attached to the plurality of chip connection members; an encapsulant that surrounds the main semiconductor chip on the upper surface of the package substrate; an auxiliary chip attached to the lower surface of the package substrate adjacent to the ponding recess through a plurality of chip terminals attached to the plurality of auxiliary chip connection pads, wherein the auxiliary chip includes first and second sides opposite to each other in a plane; a plurality of external connection terminals attached to the plurality of lower connection pads; and an underfill layer that fills a space between the package substrate and the auxiliary chip, surrounds the plurality of chip terminals, and fills the ponding recess. The ponding recess is arranged asymmetrically with respect to the auxiliary chip in a first horizontal direction perpendicular to the first side of the auxiliary chip, and a depth of the ponding recess is greater than a height of each of the plurality of chip connection members.

### BRIEF DESCRIPTION OF THE DRAWINGS

FIG. 1A is a cross-sectional view of a semiconductor package according to an embodiment of the inventive concept, FIGS. 1B and 1C illustrate the bottom of a package substrate in a semiconductor package according to an embodiment of the inventive concept, and FIG. 1D illustrates a unit element chip in a semiconductor package according to an embodiment of the inventive concept as viewed from above.

FIG. 2A is a cross-sectional view of a semiconductor package according to an embodiment of the inventive concept, and FIGS. 2B and 2C illustrate the bottom of a package substrate in a semiconductor package according to an embodiment of the inventive concept.

FIG. 3A is a cross-sectional view of a semiconductor package according to an embodiment of the inventive concept, and FIGS. 3B and 3C illustrate the bottom of a package substrate in a semiconductor package according to an embodiment of the inventive concept.

FIG. 4 is a cross-sectional view of a semiconductor package according to an embodiment of the inventive concept.

FIG. 5A is a cross-sectional view of a semiconductor package according to an embodiment of the inventive concept, and FIGS. 5B and 5C illustrate the bottom of a package substrate in a semiconductor package according to an embodiment of the inventive concept.

FIG. 6A is a cross-sectional view of a semiconductor package according to an embodiment of the inventive concept, and FIGS. 6B to 6D illustrate the bottom of a package substrate in a semiconductor package according to an embodiment of the inventive concept.

FIG. 7A is a cross-sectional view of a semiconductor package according to an embodiment of the inventive concept, and FIGS. 7B and 7C illustrate the top of a unit element chip in a semiconductor package according to an embodiment of the inventive concept.

FIGS. 8 to 14 are cross-sectional views of a package on package (PoP) type semiconductor package according to an embodiment of the inventive concept.

### DETAILED DESCRIPTION

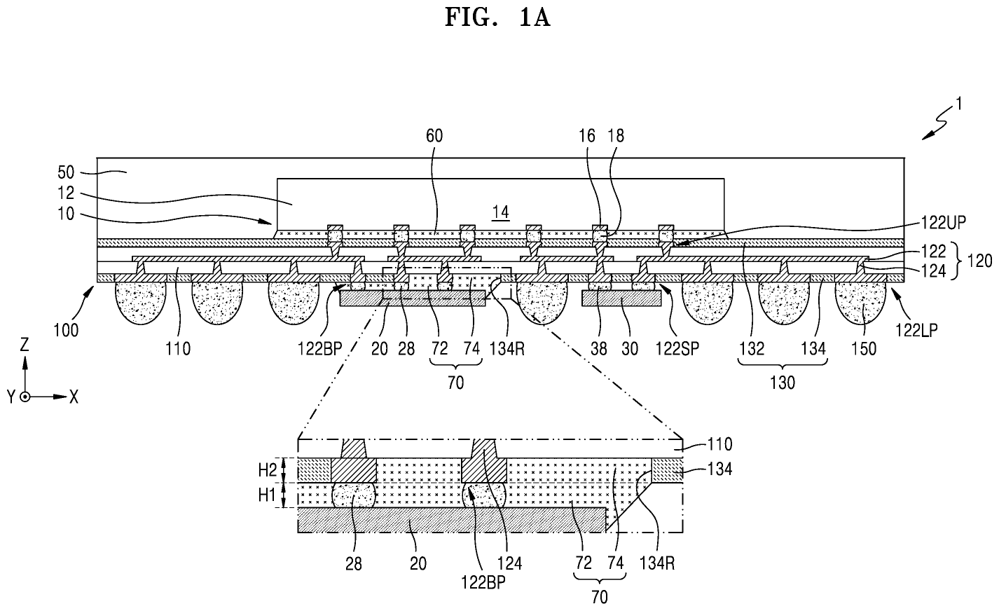

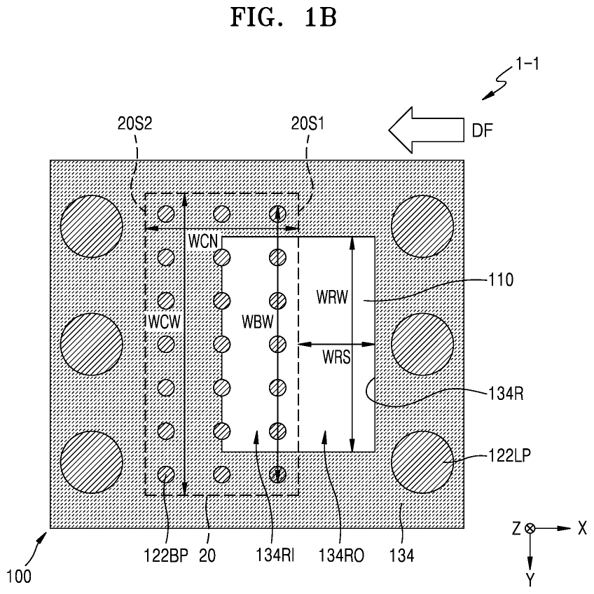

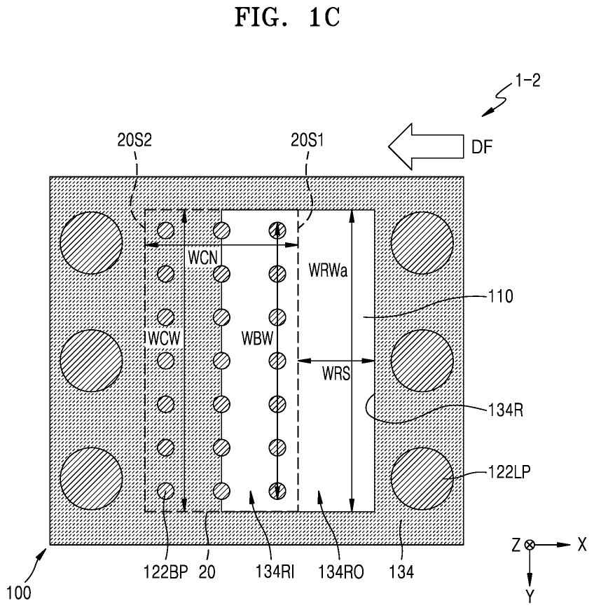

FIG. 1A is a cross-sectional view of a semiconductor package according to an embodiment of the inventive concept, FIGS. 1B and 1C illustrate the bottom of a package substrate in a semiconductor package according an embodiment of to the inventive concept, and FIG. 1D is a top view of a unit element chip in a semiconductor package according to an embodiment of the inventive concept. In the drawings, a horizontal direction may be an X direction, a Y direction, or a diagonal direction that is a linear combination of an X direction and a Y direction, and a vertical direction is a Z direction or a thickness direction that is normal to an X-Y plane that is defined by an X direction and a Y direction.

Referring to FIG. 1A, a semiconductor package 1 includes a package substrate 100, a semiconductor chip 10 attached to the upper surface of the package substrate 100, an auxiliary chip 20 attached to the lower surface of the package substrate 100, an encapsulant 50 that surrounds the semiconductor chip 10, and an underfill layer 70 that fills a space between the auxiliary chip 20 and the package substrate 100. In some embodiments, the semiconductor package 1 further includes a unit element chip 30 attached on the lower surface of the package substrate 100 and spaced apart from the auxiliary chip 20 in a horizontal direction.

In some embodiments, the package substrate 100 is a printed circuit board. For example, the package substrate 100 is a double-sided printed circuit board or a multi-layer printed circuit board. The package substrate 100 includes a substrate base 110 and a substrate wiring structure 120. The substrate wiring structure 120 includes a plurality of wiring patterns 122 placed on the upper and lower surfaces of the substrate base 110, or placed inside the substrate base 110 and that extend in the horizontal direction, and a plurality of wiring vias 124 that penetrate at least a portion of the substrate base 110 and extend in the vertical direction to electrically connect two wiring patterns 122 located at different vertical levels. In some embodiments, the substrate base 110 has a stacked structure of a plurality of base layers, and a plurality of wiring patterns 122 are placed on upper and lower surfaces of each of the plurality of base layers.

The package substrate 100 further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110. Those portion of the wiring patterns 122 placed on the upper surface of the substrate base 110 that are exposed without being covered by the upper solder resist layer 132 are referred to as a plurality of upper chip connection pads 122UP, and those portions of the wiring patterns 122 placed on the lower surface of the substrate base 110 that are exposed without being covered by the lower solder resist layer 134 are referred to as a plurality of lower surface connection pads 122LP and a plurality of auxiliary chip connection pads 122BP. A plurality of external connection terminals 150 are respectively attached to the plurality of lower connection pads 122LP. In some embodiments, the external connection terminals 150 are solder balls.

The package substrate 100 includes a ponding recess 134R that extends from the lower surface of the lower solder resist layer 134 toward the upper surface thereof. In some embodiments, the ponding recess 134R penetrates the lower solder resist layer 134 and exposes the substrate base 110 on the bottom surface thereof. The ponding recess 134R is formed by removing a portion of the lower solder resist layer 134. In some embodiments, at least some of the plurality of auxiliary chip connection pads 122BP are placed in the ponding recess 134R. The side surface of the auxiliary chip connection pad 122BP in the ponding recess 134R is exposed by not being covered by the lower solder resist layer 134.

The substrate base 110 is made of at least one material selected from phenol resin, epoxy resin, or polyimide. The substrate base 110 may include, for example, at least one material selected from Frame Retardant 4 (FR4), Tetrafunctional epoxy, Polyphenylene ether, Epoxy/polyphenylene oxide, Bismaleimide triazine (BT), Thermount, Cyanate ester, Polyimide, or Liquid crystal polymer.

The substrate wiring structure 120 includes copper. For example, each of the plurality of wiring patterns 122 and the plurality of wiring vias 124 includes at least one of electrolytically deposited (ED) copper foil, rolled-annealed (RA) copper foil, ultra-thin copper foil, sputtered copper, copper alloys, etc.

The semiconductor chip 10 includes a semiconductor substrate 12 that includes an active surface and an inactive surface opposite to each other; a semiconductor element 14 formed on the active surface of the semiconductor substrate 12; and a plurality of chip pads 16 placed on a first side of the semiconductor chip 10. The first surface of the semiconductor chip 10 and a second surface of the semiconductor chip 10 are opposite to each other, and the second surface of the semiconductor chip 10 refers to the inactive surface of the semiconductor substrate 12. Because the active surface of the semiconductor substrate 12 is adjacent to the first surface of the semiconductor chip 10, a separate illustration of the active surface of the semiconductor substrate 12 and the first surface of the semiconductor chip 10 is omitted.

In some embodiments, the semiconductor chip 10 has a face down arrangement in which the first surface thereof faces the package substrate 100, and is attached to the upper surface of the package substrate 100. The first surface of the semiconductor chip 10 is referred to as a lower surface of the semiconductor chip 10, and the second surface of the semiconductor chip 10 is referred to as an upper surface of the semiconductor chip 10. A plurality of chip connection members 18 are placed between the plurality of chip pads 16 of the semiconductor chip 10 and the plurality of upper chip connection pads 122UP of the package substrate 100. For example, the chip connection member 18 may be a solder ball or a micro bump. The semiconductor chip 10 and the package substrate 100 are electrically connected through a plurality of chip connection members 18. An underfill layer 60 is formed between the package substrate 100 and the semiconductor chip. The underfill layer 60 may be formed using, for example, a capillary underfill method. The underfill layer 60 includes, for example, epoxy resin. The underfill layer 60 surrounds the plurality of chip connection members 18.

Unless otherwise specified in the specification, the upper surface refers to a surface facing upward in the drawing, and the lower surface refers to a surface facing downward in the drawing.

The semiconductor substrate 12 includes, for example, a semiconductor material such as silicon (Si) or germanium (Ge). Alternatively, in some embodiments, the semiconductor substrate 12 includes a compound semiconductor material such as silicon carbide (SiC), gallium arsenide (GaAs), indium arsenide (InAs), or indium phosphide (InP). The semiconductor substrate 12 includes a conductive region, such as a well doped with impurities. The semiconductor substrate 12 includes various device isolation structures such as a shallow trench isolation (STI) structure.

The semiconductor element 14 includes a plurality of individual devices of various types and is formed on the active surface of the semiconductor substrate 12. The plurality of individual devices include various microelectronic devices, such as a metal-oxide-semiconductor field effect transistor (MOSFET) such as a complementary metal-insulator-semiconductor (CMOS) transistor, a system large scale integration (LSI), an active element, a passive element, etc. The plurality of individual devices are electrically connected to the conductive area of the semiconductor substrate 12. The semiconductor element 14 further includes at least two of the plurality of individual devices, or a conductive wire or a conductive plug that electrically connects the plurality of individual devices to the conductive area of the semiconductor substrate 12. In addition, each of the plurality of individual devices is electrically isolated from neighboring individual devices by an insulating film.

In some embodiments, the semiconductor chip 10 is one of a central processing unit (CPU) chip, a graphics processing unit (GPU) chip, or an application processor (AP) chip. In some embodiments, the semiconductor chip 10 is, for example, a memory semiconductor chip. The memory semiconductor chip is, for example, one of a non-volatile memory semiconductor chip such as a flash memory, a phase-change random access memory (PRAM), a magnetoresistive random access memory (MRAM), a ferroelectric random access memory (FeRAM), or a resistive random access memory (RRAM). The flash memory may be, for example, a NAND flash memory or a V-NAND flash memory. In some embodiments, the semiconductor chip 10 is a volatile memory semiconductor chip such as a dynamic random access memory (DRAM) or a static random access memory (SRAM).

The encapsulant 50 surrounds the semiconductor chip 10 on the upper surface of the package substrate 100. The encapsulant 50 covers at least a portion of the upper surface of the package substrate 100. In some embodiments, the encapsulant 50 covers all of the upper surface of the package substrate 100. In some embodiments, the encapsulant 50 covers both the upper surface and the side surface of the semiconductor chip 10. In some embodiments, the encapsulant 50 covers the side surface of the semiconductor chip 10 and exposes the upper surface of the semiconductor chip 10. The encapsulant 50 fills a space between the lower surface of the semiconductor chip 10 and the upper surface of the package substrate 100, and surrounds the plurality of chip connection members 18. For example, the encapsulant 50 is a molding member that includes an epoxy mold compound (EMC).

The auxiliary chip 20 is a different type of semiconductor chip from the semiconductor chip 10. For clarity of distinction from the auxiliary chip 20, the semiconductor chip 10 is referred to as a main semiconductor chip 10. The auxiliary chip 20 has a smaller horizontal width and smaller horizontal area than the main semiconductor chip 10, and is a semiconductor chip that assists in the operation of the main semiconductor chip 10. For example, the auxiliary chip 20 is one of a silicon capacitor, a low inductance ceramic capacitor (LICC), a controller chip, or a memory semiconductor chip, but embodiments are not necessarily limited thereto.

In some embodiments, when the main semiconductor chip 10 is a CPU chip, a GPU chip, or an AP chip, the auxiliary chip 20 is a silicon capacitor or an LICC, or a controller chip.

In some embodiments, when the main semiconductor chip 10 is a non-volatile memory semiconductor chip such as a flash memory, the auxiliary chip 20 is a controller chip that includes a control unit therein. The control unit controls access to data stored in the main semiconductor chip 10. For example, the control unit controls a write/read operation of the main semiconductor chip 10, such as a flash memory, according to a control command from an external host. The control unit performs wear leveling, garbage collection, bad block management, and error correction code (ECC) on the non-volatile memory semiconductor chip.

In some embodiments, when the main semiconductor chip 10 is a memory semiconductor chip, the auxiliary chip 20 is a memory semiconductor chip whose capacity and/or operation speed differ from that of the main semiconductor chip 10. For example, the auxiliary chip 20 is a memory semiconductor chip that performs a buffer function.

The auxiliary chip 20 is connected to the plurality of auxiliary chip connection pads 122BP of the package substrate 100 through a plurality of chip terminals 28. In some embodiments, the plurality of chip terminals 28 are micro pins or micro bumps attached to the upper surface of the auxiliary chip 20, but embodiments are not necessarily limited thereto. For example, the auxiliary chip 20 has four or more chip terminals 28. In some embodiments, the auxiliary chip 20 has a plurality of connection pads similar to the plurality of chip pads 16 of the semiconductor chip 10, and the plurality of chip terminals 28 are solder balls or micro bumps formed between the plurality of connection pads and some of the plurality of substrate lower pads 124.

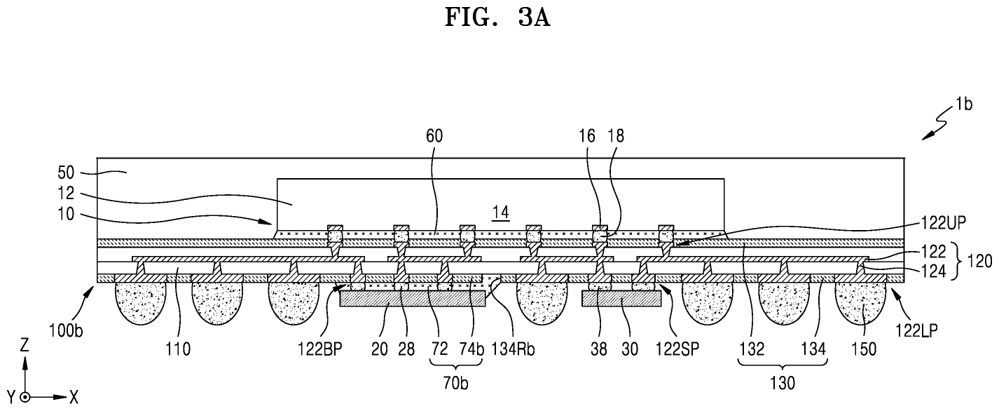

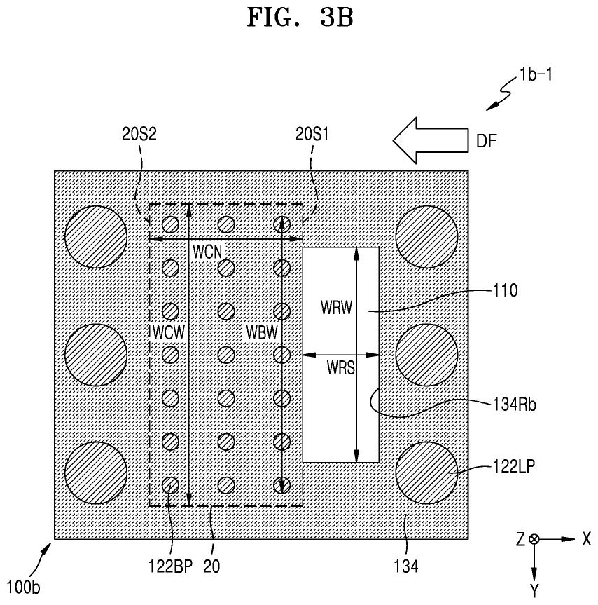

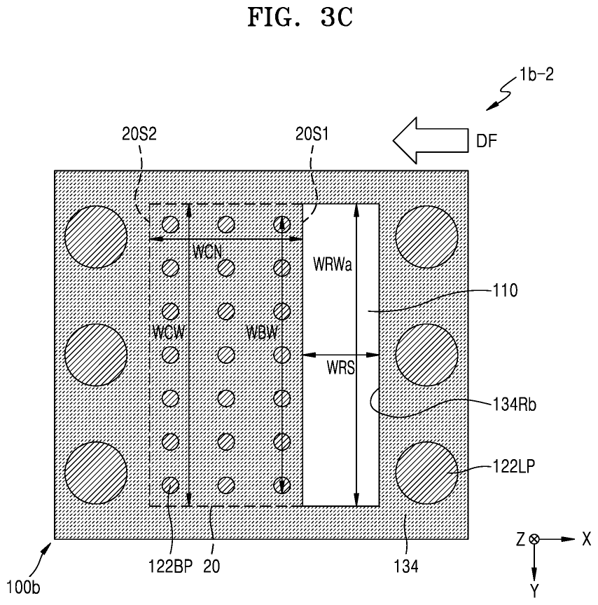

In some embodiments, the auxiliary chip 20 are attached to the lower surface of the package substrate 100 so that at least a part thereof overlaps the ponding recess 134R in the vertical direction. The ponding recess 134R extends from the portion of the package substrate 100 adjacent to the auxiliary chip 20 to the portion of the package substrate 100 that overlaps the auxiliary chip 20 in the vertical direction (Z direction) so that a portion of the auxiliary chip 20 and a portion of the ponding recess 134R overlap in the vertical direction. In some embodiments, the ponding recess 134R is formed in a portion of the package substrate 100 adjacent to the auxiliary chip 20, or the ponding recess 134R is formed in the entire portion of the package substrate 100 that overlaps the auxiliary chip 20 in the vertical direction, as described in detail with reference to FIGS. 3A to 6D.

The underfill layer 70 surrounds the plurality of chip terminals 28 and fills a space between the auxiliary chip 20 and the package substrate 100. The underfill layer 70 includes a resin. For example, the underfill layer 70 is formed of an epoxy resin by a capillary under-fill method. A filler may be mixed in the underfill layer 70, and the filler may be formed of, for example, silica.

The underfill layer 70 fills the ponding recess 134R. The underfill layer 70 includes a first underfill portion 72 that surrounds the plurality of chip terminals 28 on the lower surface of the lower solder resist layer 134 and a second underfill portion 74 above the lower surface of the lower solder resist layer 134 that fills the ponding recess 134R. The first underfill portion 72 and the second underfill portion 74 are formed together as an integral body. The first underfill portion 72 has a first height H1, and the second underfill portion 74 has a second height H2. Each of the plurality of chip terminals 28 has a first height H1, and each of the thickness of the lower solder resist layer 134 and the depth of the ponding recess 134R are equal to the second height H2. The first height H1 is from about 3 μm to about 50 μm, and the second height H2 is from about 5 μm to about 20 μm. In some embodiments, when the first height H1 is from about 3 μm to about 15 μm, the second height H2 is greater than the first height H1.

The first underfill portion 72 covers the upper surface of the auxiliary chip 20 and surrounds the plurality of chip terminals 28. The second underfill portion 74 surrounds the auxiliary chip connection pad 122BP and is placed in the ponding recess 134R. For example, the first underfill portion 72 covers side surfaces of the plurality of chip terminals 28, and the second underfill portion 74 covers the side surface of the auxiliary chip connecting pad 122BP in the ponding recess 134R.

The underfill layer 70 fills a space between the auxiliary chip 20 and the package substrate 100 and the ponding recess 134R and is formed by injecting the resin through the portion of the ponding recess 134R that does not overlap the auxiliary chip 20 in the vertical direction.

The main semiconductor chip 10 has a greater horizontal width and greater horizontal area than the auxiliary chip 20, and the encapsulant 50 has a greater horizontal width and greater horizontal area than the underfill layer 70.

Referring to FIG. 1B, in some embodiments, a semiconductor package 1-1 includes a package substrate 100. The semiconductor package 1-1 may be the semiconductor package 1 shown in FIG. 1A.

The package substrate 100 includes a lower solder resist layer 134 that covers a portion of the lower surface of the substrate base 110. The auxiliary chip 20 attached to the lower surface of the package substrate 100 includes a first side 2051 and a second side 20S2 opposite to each other in a planar area (X-Y plane). The package substrate 100 includes a ponding recess 134R that extends from the lower surface of the lower solder resist layer 134 toward the upper surface thereof. The ponding recess 134R penetrates the lower solder resist layer 134 and exposes the bottom surface of the substrate base 110.

A part of the ponding recess 134R overlaps the auxiliary chip 20 in the vertical direction, and the other part does not overlap the auxiliary chip 20. In an X-Y plane, the ponding recess 134R extends from the outside of the auxiliary chip 20 to the inside of the auxiliary chip 20. For example, the ponding recess 134R extends in a direction opposite to a first horizontal direction (an X direction) in the X-Y plane from outside of the auxiliary chip 20 over the first side 20S1 of the auxiliary chip 20 to cover the inside of the auxiliary chip 20, and the direction opposite to the first horizontal direction (X direction) is an injection direction DF into which a resin that forms the underfill layer 70 shown in FIG. 1A is injected. The extension direction of the first side 20S1 is a second horizontal direction (Y direction) perpendicular to the injection direction DF. That is, the ponding recess 134R extends in the injection direction DF in the X-Y plane from outside of the auxiliary chip 20 over the first side 20S1 of the auxiliary chip 20 to cover the inside of the auxiliary chip 20.

The ponding recess 134R includes an inner recess part 134RI that overlaps the auxiliary chip 20 in the vertical direction and an outer recess part 134RO that does not overlap the auxiliary chip 20. The inner recess part 134RI and the outer recess part 134RO are connected to each other. In some embodiments, in an X-Y plane, the outer recess part 134RO is formed outside of the auxiliary chip 20 on one side of the first side 20S1 of the auxiliary chip 20, and the inner recess part 134RI is formed over the auxiliary chip 20 on the other side of the first side 20S1 of the auxiliary chip 20. For example, the ponding recess 134R is asymmetrically placed with respect to the auxiliary chip 20 in the X-Y plane.

The auxiliary chip 20 has a first width WCN in the injection direction DF and a second width WCW in a direction perpendicular to the injection direction DF. In some embodiments, the second width WCW is a greater than the first width WCN. The outer recess part 134RO of the ponding recess 134R has a third width WRS in the injection direction DF, and a fourth width WRW in a direction perpendicular to the injection direction DF. A plurality of auxiliary chip connection pads 122BP are arranged in a column in a direction perpendicular to the injection direction DF, and the column formed by the plurality of auxiliary chip connection pads 122BP has a fifth width WBW. The fifth width WBW is less than the second width WCW. The fifth width WBW is greater than the fourth width WRW. The third width WRS is equal to or greater than ⅓ of the first width WCN, and the fourth width WRW is greater than or equal to ½ of the second width WCW. In some embodiments, the fourth width WRW is less than the second width WCW. The third width WRS is twice or more than a pitch of the arrangement of the plurality of auxiliary chip connecting pads 122BP in the horizontal direction.

Referring to FIG. 1C, in some embodiments, a semiconductor package 1-2 includes a package substrate 100. The semiconductor package 1-2 may be the semiconductor package 1 shown in FIG. 1A.

The package substrate 100 includes a lower solder resist layer 134 that covers a portion of the lower surface of the substrate base 110, and an auxiliary chip 20 attached to the lower surface of the package substrate 100. The auxiliary chip 20 includes a first side 20S1 and a second side 20S2 opposite to each other in an X-Y plane area. The package substrate 100 includes a ponding recess 134R that extends from the lower surface of the lower solder resist layer 134 toward the upper surface thereof. The ponding recess 134R penetrates the lower solder resist layer 134 and exposes the bottom surface of the substrate base 110.

A part of the ponding recess 134R overlaps in the vertical direction the auxiliary chip 20, and the other part does not overlap the auxiliary chip 20. In the X-Y plane, the ponding recess 134R extends from outside of the auxiliary chip 20 to cover the inside of the auxiliary chip 20. For example, the ponding recess 134R extends in a direction opposite to the first horizontal direction (X direction) in the X-Y plane from outside of the auxiliary chip 20 over the first side 20S1 of the auxiliary chip 20 to cover the inside of the auxiliary chip 20, and a direction opposite to the first horizontal direction (X direction) is an injection direction DF into which a resin that forms the underfill layer 70 shown in FIG. 1A is injected. That is, the ponding recess 134R extends in the injection direction DF in the X-Y plane from outside of the auxiliary chip 20 over the first side 20S1 of the auxiliary chip 20 to cover the inside of the auxiliary chip 20.

The ponding recess 134R is formed of an inner recess part 134RI that overlaps the auxiliary chip 20 in the vertical direction and an outer recess part 134RO that does not overlap the auxiliary chip 20. In some embodiments, in the X-Y plane, the outer recess part 134RO is formed outside of the auxiliary chip 20 on one side of the first side 20S1 of the auxiliary chip 20, and the inner recess part 134RI is formed over the auxiliary chip 20 on the other side of the first side 20S1 of the auxiliary chip 20. For example, the ponding recess 134R is asymmetrically placed with respect to the auxiliary chip 20 in the X-Y plane.

The auxiliary chip 20 has a first width WCN in the injection direction DF and a second width WCW in a direction perpendicular to the injection direction DF. In some embodiments, the second width WCW is greater than the first width WCN. The outer recess part 134RO of the ponding recess 134R has a third width WRS in the injection direction DF, and a fourth width WRWa in a direction perpendicular to the injection direction DF. A column formed by the plurality of auxiliary chip connection pads 122BP in a direction perpendicular to the injection direction DF has a fifth width WBW. The fifth width WBW is less than the second width WCW. The third width WRS is equal to or greater than ⅓ of the first width WCN, and the fourth width WRWa is greater than or equal to ½ of the second width WCW. In some embodiments, the fourth width WRWa is equal to the second width WCW. For example, the fourth width WRWa is greater than the fifth width WBW.

Referring to FIGS. 1A to 1C together, the semiconductor packages 1, 1-1, and 1-2 according to embodiments of the inventive concept include a package substrate 100 that includes a ponding recess 134R that extends from the lower surface of the lower solder resist layer 134 toward the upper surface thereof. The underfill layer 70 surrounds the plurality of chip terminals 28 and fills a space between the auxiliary chip 20 and the package substrate 100. The underfill layer 70 surrounds the auxiliary chip connecting pad 122BP and the plurality of chip terminals 28 and fills the space between the upper surface of the auxiliary chip 20 and the lower surface of the package substrate 100, and fills the ponding recess 134R.

The resin that forms the underfill layer 70 is injected through the outer recess part 134RO, which is a part of the ponding recess 134R that does not overlap the auxiliary chip 20 in the vertical direction, and flows across the first side 20S1 of the auxiliary chip 20 in the injection direction DF to fill the ponding recess 134R between the auxiliary chip 20 and the package substrate 100. Because the resin that forms the underfill layer 70 fills the ponding recess 134R, a bleed shape is prevented in which the resin overflows out of the second side 20S2 of the auxiliary chip 20 from between the auxiliary chip 20 and the package substrate 100 and spreads along the lower surface of the package substrate 100.

Therefore, because the underfill layer 70 is spaced apart from the plurality of lower connection pads 122LP adjacent to the auxiliary chip 20, the underfill layer 70 does not cover the plurality of lower connection pads 122LP, and the reliability of electrical connection between the plurality of lower connection pads 122LP and the plurality of external connection terminals 150 is secured.

In addition, because the underfill layer 70 does not overflow out from between the auxiliary chip 20 and the package substrate 100, the underfill layer 70 fills the space between the auxiliary chip 20 and the package substrate 100. Therefore, the bonding strength between the plurality of chip terminals 28 and the package substrate 100 and the bonding strength between the plurality of chip terminals 28 and the auxiliary chip 20 is increased, and the reliability of the electrical connection between the package substrate 100 and the auxiliary chip 20 through the plurality of chip terminals 28 is secured.

Refer to FIGS. 1A and 1D together, in some embodiments, the semiconductor package 1 further includes a unit element chip 30 attached to the lower surface of the package substrate 100. The unit element chip 30 is attached to the lower surface of the package substrate 100 and is spaced apart from the auxiliary chip 20 in a horizontal direction.

The unit element chip 30 may be a passive element or an active element. For example, the passive element may be a resistor, an inductor, or a capacitor, and the active element may be a transistor, a diode, or an operational amplifier. In some embodiments, the unit element chip 30 is an intermediate storage capacitor (ISC). For example, the unit element chip 30 may be a ceramic capacitor or a ceramic resistor.

The plurality of wiring patterns 122 include a plurality of lower connection pads 122LP, a plurality of auxiliary chip connection pads 122BP, and a plurality of device connection pads 122SP that are exposed portions placed on the lower surface of the substrate base 110 and not covered by the lower solder resist layer 134.

The unit element chip 30 is connected to the plurality of element connection pads 122SP of the package substrate 100 through a plurality of element terminals 38. In some embodiments, the plurality of element terminals 38 are micro pins or micro bumps attached to the upper surface of the unit element chip 30, or is a solder paste on which the unit element chip 30 is placed, but embodiments of the inventive concept are not necessarily limited thereto. For example, in some embodiments, the unit element chip 30 has two element terminals 38.

In some embodiments, a material layer that surrounds the plurality of element terminals 38, such as the underfill layer 70, is not placed between the unit element chip 30 and the package substrate 100. For example, the side surfaces of the plurality of element terminals 38 are externally exposed. In some embodiments, the sum of the horizontal areas of the plurality of element terminals 38 in the X-Y plane is ⅓ or greater of the horizontal area of the unit element chip 30.

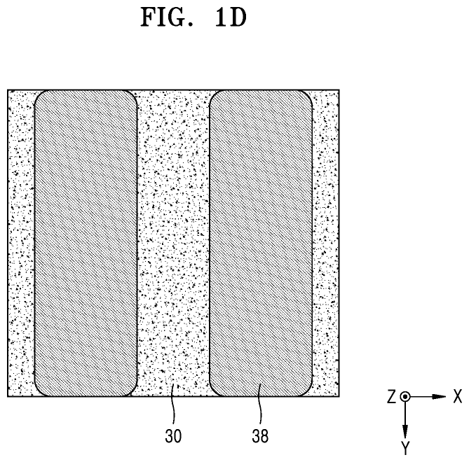

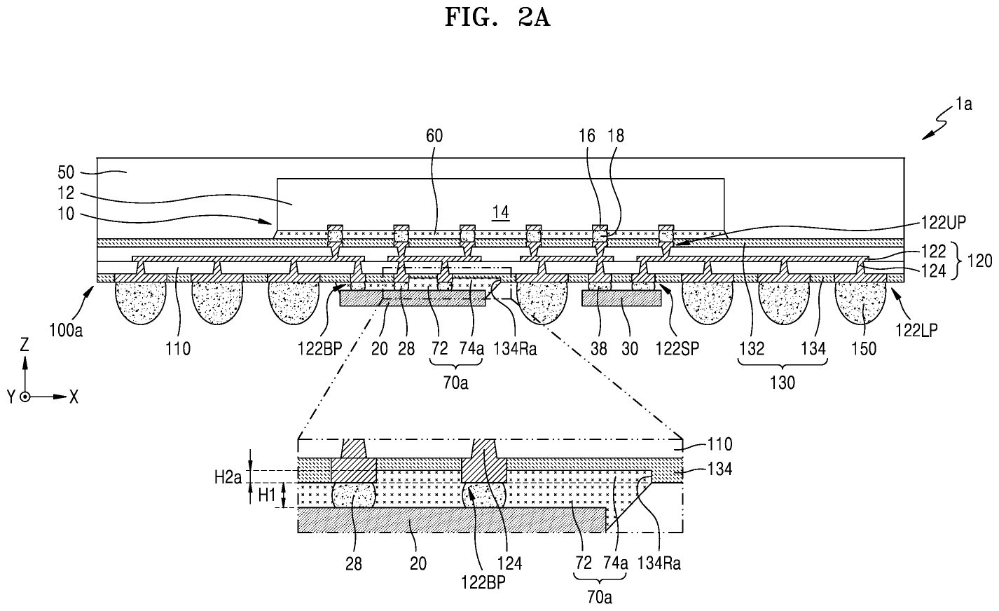

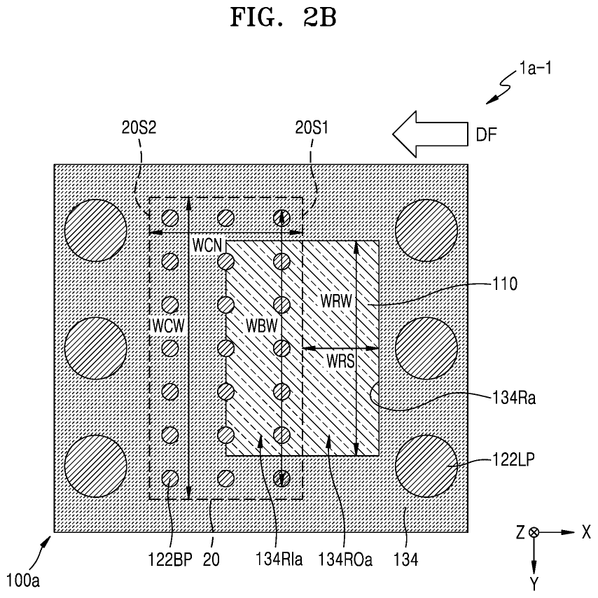

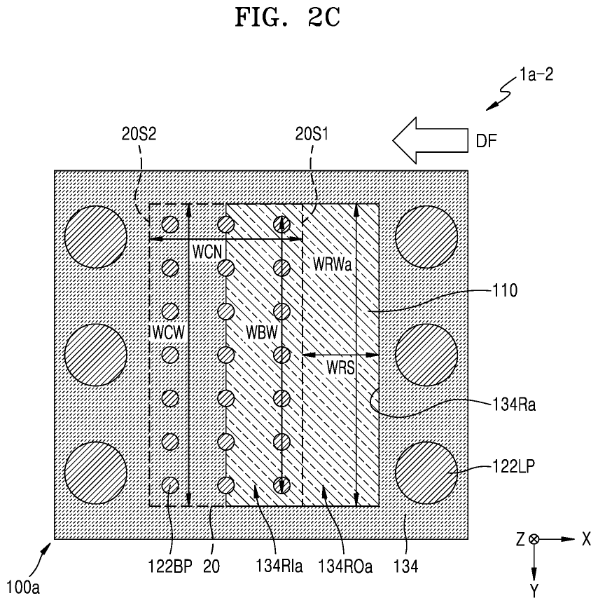

FIG. 2A is a cross-sectional view of a semiconductor package according to an embodiment of the inventive concept, and FIGS. 2B and 2C illustrate the bottom of the package substrate in a semiconductor package according to an embodiment of the inventive concept. In the descriptions of FIGS. 2A to 2C, repeated descriptions of components shown in FIGS. 1A to 1D may be omitted.

Referring to FIG. 2A, in an embodiment, a semiconductor package 1a includes a package substrate 100a, a semiconductor chip 10 attached to the upper surface of the package substrate 100a, an auxiliary chip 20 attached to the lower surface of the package substrate 100a, an encapsulant 50 that surrounds the semiconductor chip 10, and an underfill layer 70a that fills the space between the auxiliary chip 20 and the package substrate 100a. In some embodiments, the semiconductor package 1a further include sa unit element chip 30 attached onto the lower surface of the package substrate 100a and spaced apart from the auxiliary chip 20 in a horizontal direction.

In some embodiments, the package substrate 100a is a printed circuit board. The package substrate 100a includes a substrate base 110 and a substrate wiring structure 120. The package substrate 100a further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110.

The package substrate 100a includes a ponding recess 134Ra that extends from the lower surface of the lower solder resist layer 134 toward the upper surface thereof. In some embodiments, the ponding recess 134Ra does not extend from the lower surface to the upper surface of the lower solder resist layer 134, so that the bottom surface of the substrate base 110 is not exposed and a portion of a bottom surface of the lower solder resist layer 134 is exposed. The ponding recess 134Ra is formed by removing a portion of the lower solder resist layer 134. In some embodiments, at least some of the plurality of auxiliary chip connection pads 122BP are placed in the ponding recess 134Ra. At least a portion of the side surface of the auxiliary chip connection pad 122BP in the ponding recess 134Ra are exposed by not being covered by the lower solder resist layer 134.

The auxiliary chip 20 is connected to the plurality of auxiliary chip connection pads 122BP of the package substrate 100a through the plurality of chip terminals 28. In some embodiments, the auxiliary chip 20 is attached to the lower surface of the package substrate 100a so that at least a part thereof overlaps the ponding recess 134Ra in the vertical direction. The ponding recess 134Ra extends in the vertical direction from the portion of the package substrate 100a adjacent to the auxiliary chip 20 to the portion of the package substrate 100a that overlaps the auxiliary chip 20 so that a portion of the auxiliary chip 20 and a portion of the ponding recess 134Ra overlap in the vertical direction.

The underfill layer 70a surrounds the plurality of chip terminals 28 and fills a space between the auxiliary chip 20 and the package substrate 100a. The underfill layer 70a fills the ponding recess 134Ra. The underfill layer 70a includes a first underfill portion 72 positioned below the lower surface of the lower solder resist layer 134 and that surrounds the plurality of chip terminals 28 and a second underfill portion 74a positioned on the upper side of the lower surface of the lower solder resist layer 134 and that fills the ponding recess 134Ra. The first underfill portion 72 and the second underfill portion 74a are formed together an integral body. The first underfill portion 72 has a first height H1, and the second underfill portion 74a has a second height H2a. Each of the plurality of chip terminals 28 has the first height H1, the thickness of the lower solder resist layer 134 is greater than the second height H2a, and the depth of the ponding recess 134Ra is equal to the second height H2a. The first height H1 is from about 3 μm to about 50 μm, and the second height H2a is from about 5 μm to about 15 μm.

The first underfill portion 72 covers the upper surface of the auxiliary chip 20 and surrounds the plurality of chip terminals 28. The second underfill portion 74a surrounds the auxiliary chip connection pad 122BP and fills the ponding recess 134Ra. For example, the first underfill portion 72 covers side surfaces of the plurality of chip terminals 28, and the second underfill portion 74a covers the side surface of the auxiliary chip connecting pad 122BP in the ponding recess 134Ra.

The underfill layer 70a fills a space between the auxiliary chip 20 and the package substrate 100 and the ponding recess 134Ra is formed by injecting the resin through the portion of the ponding recess 134Ra that does not overlap the auxiliary chip 20 in the vertical direction.

The main semiconductor chip 10 has a greater horizontal width and greater horizontal area than the auxiliary chip 20, and the encapsulant 50 has a greater horizontal width and greater horizontal area than the underfill layer 70a.

Referring to FIG. 2B, in an embodiment, a semiconductor package 1a-1 includes a package substrate 100a. The semiconductor package 1a-1 may be the semiconductor package 1a shown in FIG. 2A.

The package substrate 100a includes a lower solder resist layer 134 that covers a portion of the lower surface of the substrate base 110. The auxiliary chip 20 attached to the lower surface of the package substrate 100a includes a first side 2051 and a second side 20S2 opposite to each other in a planar area in the X-Y plane. The package substrate 100a includes a ponding recess 134Ra that extends from the lower surface of the lower solder resist layer 134 toward the upper surface thereof. The ponding recess 134Ra does not completely penetrate the lower solder resist layer 134, so that the bottom surface of the substrate base 110 is not exposed, and a portion of the lower solder resist layer 134 is exposed.

A part of the ponding recess 134Ra overlaps the auxiliary chip 20 in the vertical direction, and the other part does not overlap the auxiliary chip 20. In the X-Y plane, the ponding recess 134Ra extends from outside of the auxiliary chip 20 to cover the inside of the auxiliary chip 20. For example, the ponding recess 134Ra extends in the injection direction DF from outside of the auxiliary chip 20 over the first side 20S1 of the auxiliary chip 20 to cover the inside of the auxiliary chip 20.

The ponding recess 134Ra includes an inner recess part 134RIa that overlaps the auxiliary chip 20 in the vertical direction and an outer recess part 134ROa that does not overlap the auxiliary chip 20. In some embodiments, in the X-Y plane, the outer recess part 134ROa is formed outside of the auxiliary chip 20 on one side of the first side 20S1 of the auxiliary chip 20, and the inner recess part 134RIa is formed over the auxiliary chip 20 on the other side of the first side 20S1 of the auxiliary chip 20. For example, the ponding recess 134Ra is asymmetrically placed with respect to the auxiliary chip 20 in the X-Y plane.

The auxiliary chip 20 has a first width WCN in the injection direction DF and a second width WCW in a direction perpendicular to the injection direction DF. In some embodiments, the second width WCW is greater than the first width WCN. The outer recess part 134ROa of the ponding recess 134Ra has a third width WRS in the injection direction DF, and a fourth width WRW in a direction perpendicular to the injection direction DF. A column formed by the plurality of auxiliary chip connection pads 122BP in a direction perpendicular to the injection direction DF has a fifth width WBW. The fifth width WBW is less than the second width WCW. The third width WRS is equal to or greater than ⅓ of the first width WCN, and the fourth width WRW is greater than or equal to ½ of the second width WCW. In some embodiments, the fourth width WRW is less than the second width WCW.

Referring to FIG. 2C, in an embodiment, a semiconductor package 1a-2 includes a package substrate 100a. The semiconductor package 1a-2 may be the semiconductor package 1a shown in FIG. 2A.

The ponding recess 134Ra includes an inner recess part 134RIa that overlaps the auxiliary chip 20 in the vertical direction and an outer recess part 134ROa that does not overlap the auxiliary chip 20. In some embodiments, in an X-Y plane, the outer recess part 134ROa is formed outside of the auxiliary chip 20 on one side of the first side 20S1 of the auxiliary chip 20, and the inner recess part 134RIa is formed over the auxiliary chip 20 on the other side of the first side 20S1 of the auxiliary chip 20. For example, the ponding recess 134Ra is asymmetrically placed with respect to the auxiliary chip 20 in the X-Y plane.

The auxiliary chip 20 has a first width WCN in the injection direction DF and a second width WCW in a direction perpendicular to the injection direction DF. In some embodiments, the second width WCW may have a greater value than the first width WCN. The outer recess part 134ROa of the ponding recess 134Ra has a third width WRS in the injection direction DF, and a fourth width WRWa in a direction perpendicular to the injection direction DF. A column formed by the plurality of auxiliary chip connection pads 122BP in a direction perpendicular to the injection direction DF has a fifth width WBW. The fifth width WBW is less than the second width WCW. The third width WRS is equal to or greater than ⅓ of the first width WCN, and the fourth width WRWa is greater than or equal to ½ of the second width WCW. In some embodiments, the fourth width WRWa is equal to the second width WCW. For example, the fourth width WRWa is greater than the fifth width WBW.

Referring to FIGS. 2A to 2C together, the semiconductor packages 1a, 1a-1, and 1a-2 according to embodiments of the inventive concept include a package substrate 100a that includes a ponding recess 134Ra that extends from the lower surface of the lower solder resist layer 134 toward the upper surface thereof. The underfill layer 70a surrounds the plurality of chip terminals 28 and fills a space between the auxiliary chip 20 and the package substrate 100a. The underfill layer 70a surrounds the auxiliary chip connecting pad 122BP and fills the space between the upper surface of the auxiliary chip 20 and the lower surface of the package substrate 100a, and fills the ponding recess 134Ra.

The resin that forms the underfill layer 70a is injected through the outer recess part 134ROa, which is a part of the ponding recess 134Ra that does not overlap the auxiliary chip 20 in the vertical direction (Z direction), and flows across the first side 20S1 of the auxiliary chip 20 in the injection direction DF and fills the ponding recess 134Ra and the space between the auxiliary chip 20 and the package substrate 100a. Because the resin fills the ponding recess 134Ra, a bleed shape is prevented in which the resin overflows out from the second side 20S2 of the auxiliary chip 20 and from between the auxiliary chip 20 and the package substrate 100a and spreads along the lower surface of the package substrate 100a.

Therefore, because the underfill layer 70a is spaced apart from the plurality of lower connection pads 122LP adjacent to the auxiliary chip 20, the underfill layer 70 does not cover the plurality of lower connection pads 122LP, and the reliability of electrical connection between the plurality of lower connection pads 122LP and the plurality of external connection terminals 150 is secured.

In addition, because the underfill layer 70a does not overflow out from the second side 20S2 of the auxiliary chip 20 from between the auxiliary chip 20 and the package substrate 100a, the underfill layer 70 fills the space between the auxiliary chip 20 and the package substrate 100a. Therefore, the bonding strength between the plurality of chip terminals 28 and the package substrate 100a and the bonding strength between the plurality of chip terminals 28 and the auxiliary chip 20 is increased, and the reliability of the electrical connection between the package substrate 100a and the auxiliary chip 20 through the plurality of chip terminals 28 is secured.

FIG. 3A is a cross-sectional view of a semiconductor package according to an embodiment of the inventive concept, and FIGS. 3B and 3C illustrate the bottom of a package substrate in a semiconductor package according to an embodiment of the inventive concept. In the descriptions of FIGS. 3A to 3C, repeated descriptions of components shown in FIGS. 1A to 1D may be omitted.

Referring to FIG. 3A, in some embodiments, a semiconductor package 1b includes a package substrate 100b, a semiconductor chip 10 attached to the upper surface of the package substrate 100b, an auxiliary chip 20 attached to the lower surface of the package substrate 100b, an encapsulant 50 that surrounds the semiconductor chip 10, and an underfill layer 70b that fills the space between the auxiliary chip 20 and the package substrate 100b. In some embodiments, the semiconductor package 1b further includes a unit element chip 30 attached to the lower surface of the package substrate 100b.

In some embodiments, the package substrate 100b is a printed circuit board. The package substrate 100b includes a substrate base 110 and a substrate wiring structure 120. The package substrate 100b further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110. The package substrate 100b includes a ponding recess 134Rb that extends from the lower surface of the lower solder resist layer 134 toward the upper surface thereof. In some embodiments, the ponding recess 134Rb penetrates the lower solder resist layer 134 and exposes the bottom surface of the substrate base 110.

The ponding recess 134Rb is formed in a portion of the package substrate 100b adjacent to the auxiliary chip 20. The ponding recess 134Rb is formed in a portion of the package substrate 100b that does not overlap the auxiliary chip 20 in the vertical direction.

The underfill layer 70b surrounds the plurality of chip terminals 28 and fills a space between the auxiliary chip 20 and the package substrate 100b. The underfill layer 70b includes a resin. The underfill layer 70b fills the ponding recess 134Rb. The underfill layer 70b includes a first underfill portion 72 positioned below the lower surface of the lower solder resist layer 134 and that surrounds the plurality of chip terminals 28 and a second underfill portion 74b positioned above the lower surface of the lower solder resist layer 134 and that fills the ponding recess 134Rb. The first underfill portion 72 and the second underfill portion 74b are formed together as an integral body.

The first underfill portion 72 covers the upper surface of the auxiliary chip 20 and surrounds the plurality of chip terminals 28. The second underfill portion 74b fills the ponding recess 134Rb. The auxiliary chip connection pad 122BP are not placed in the ponding recess 134Rb, and the second underfill portion 74b does not cover the side surface of the auxiliary chip connection pad 122BP.

The underfill layer 70b fills the ponding recess 134Rb and the space between the auxiliary chip 20 and the package substrate 100b and is formed by injecting a resin through a portion of the ponding recess 134Rb. The ponding recess 134Rb is substantially similar to the outer recess part 134RO described with reference to FIGS. 1A to 1C. For example, the semiconductor package 1b does not have the inner recess part 134RI of the semiconductor packages 1, 1-1, and 1-2 shown in FIGS. 1A to 1C, but includes the ponding recess part 134Rb that corresponds to the outer recess part 134RO.

Referring to FIG. 3B, in some embodiments, the semiconductor package 1b-1 includes a package substrate 100b. The semiconductor package 1b-1 may be the semiconductor package 1b shown in FIG. 3A.

The package substrate 100b includes a lower solder resist layer 134 that covers a portion of the lower surface of the substrate base 110, and the auxiliary chip 20 attached to the lower surface of the package substrate 100b includes a first side 20S1 and a second side 20S2 opposite to each other in an X-Y plane. The package substrate 100b includes a ponding recess 134Rb that extends from the lower surface of the lower solder resist layer 134 toward the upper surface thereof. The ponding recess 134Rb penetrates the lower solder resist layer 134 and exposes the bottom surface of the substrate base 110.

The ponding recess 134Rb is formed in a portion of the package substrate 100b adjacent to the auxiliary chip 20. The ponding recess 134Rb is formed in a portion of the package substrate 100b that does not overlap the auxiliary chip 20 in the vertical direction. For example, the ponding recess 134Rb is formed in a portion of the package substrate 100b outside of the auxiliary chip 20 adjacent to the first side 20S1 of the auxiliary chip 20 in the X-Y plane.

The auxiliary chip 20 has a first width WCN in the injection direction DF and a second width WCW in a direction perpendicular to the injection direction DF. In some embodiments, the second width WCW is greater than the first width WCN. The ponding recess 134Rb has a third width WRS in the injection direction DF, and a fourth width WRW in a direction perpendicular to the injection direction DF. A column formed by the plurality of auxiliary chip connection pads 122BP in a direction perpendicular to the injection direction DF has a fifth width WBW. The fifth width WBW is less than the second width WCW. The fifth width WBW is greater than the fourth width WRW. The third width WRS is equal to or greater than ⅓ of the first width WCN, and the fourth width WRW is greater than or equal to ½ of the second width WCW. In some embodiments, the fourth width WRW is less than the second width WCW.

Referring to FIG. 3C, in some embodiments, the semiconductor package 1b-2 includes a package substrate 100b. The semiconductor package 1b-2 may be the semiconductor package 1b shown in FIG. 3A.

The ponding recess 134Rb is formed in a portion of the package substrate 100b adjacent to the auxiliary chip 20. The ponding recess 134Rb is formed in a portion of the package substrate 100b that does not overlap the auxiliary chip 20 in the vertical direction. For example, the ponding recess 134Rb is formed in a portion of the package substrate 100b outside of the auxiliary chip 20 adjacent to the first side 20S1 of the auxiliary chip 20 in the X-Y plane.

The auxiliary chip 20 has a first width WCN in the injection direction DF and a second width WCW in a direction perpendicular to the injection direction DF. In some embodiments, the second width WCW is greater than the first width WCN. The ponding recess 134Rb has a third width WRS in the injection direction DF, and a fourth width WRWa in a direction perpendicular to the injection direction DF. A column formed by the plurality of auxiliary chip connection pads 122BP in a direction perpendicular to the injection direction DF has a fifth width WBW. The fifth width WBW is less than the second width WCW. The third width WRS is equal to or greater than ⅓ of the first width WCN, and the fourth width WRWa is greater than or equal to ½ of the second width WCW. In some embodiments, the fourth width WRWa is equal to the second width WCW. For example, the fourth width WRWa is a greater than the fifth width WBW.

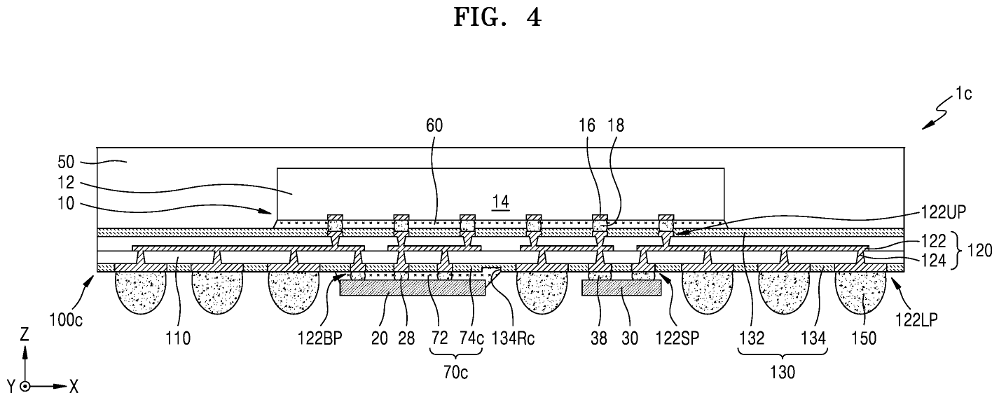

FIG. 4 is a cross-sectional view illustrating a semiconductor package according to the inventive concept. In the descriptions of FIG. 4, descriptions of components shown in FIGS. 2A to 2C and FIGS. 3A to 3C may be omitted.

Referring to FIG. 4, in an embodiment, a semiconductor package 1c includes a package substrate 100c, a semiconductor chip 10 attached to the upper surface of the package substrate 100c, an auxiliary chip 20 attached to the lower surface of the package substrate 100c, an encapsulant 50 that surrounds the semiconductor chip 10, and an underfill layer 70c that fills the space between the auxiliary chip 20 and the package substrate 100c. In some embodiments, the semiconductor package 1c further includes a unit element chip 30 attached to the lower surface of the package substrate 100c.

In some embodiments, the package substrate 100c is a printed circuit board. The package substrate 100c includes a substrate base 110 and a substrate wiring structure 120. The package substrate 100c further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110. The package substrate 100c includes a ponding recess 134Rc that extends from the lower surface of the lower solder resist layer 134 toward the upper surface thereof. In some embodiments, the ponding recess 134Rc does not extend from the lower surface to the upper surface of the lower solder resist layer 134, so that the bottom surface of the substrate base 110 is not exposed and a portion of the bottom surface of the lower solder resist layer 134 is exposed.

The ponding recess 134Rc is formed in a portion of the package substrate 100c adjacent to the auxiliary chip 20. The ponding recess 134Rc is formed in a portion of the package substrate 100c that does not overlap with the auxiliary chip 20 in the vertical direction. For example, the ponding recess 134Rc is formed in a portion of the package substrate 100c outside the auxiliary chip 20 and adjacent to the first side 20S1 of the auxiliary chip 20 in an X-Y plane.

The underfill layer 70c surrounds the plurality of chip terminals 28 and fills a space between the auxiliary chip 20 and the package substrate 100c. The underfill layer 70c includes a resin. The underfill layer 70c fills the ponding recess 134Rc. The underfill layer 70c includes a first underfill portion 72 positioned on the lower side of the lower solder resist layer 134 and that surrounds the plurality of chip terminals 28 and a second underfill portion 74c positioned on the upper side of the lower solder resist layer 134 and that fills the ponding recess 134Rc. The first underfill portion 72 and the second underfill portion 74c are formed together as an integral body.

The underfill layer 70c fills the ponding recess 134Rc and the space between the auxiliary chip 20 and the package substrate 100c and is formed by injecting a resin through a portion of the ponding recess 134Rc. The ponding recess 134Rc is substantially similar to the outer recess part 134ROa described with reference to FIGS. 2A to 2C. For example, the semiconductor package 1c does not have the inner recess part 134RIa of the semiconductor packages 1a, 1a-1, and 1a-2 shown in FIGS. 2A to 2C, but has only the ponding recess part 134Rc that corresponds to the outer recess part 134ROa. The planar shape of the ponding recess 134Rc is substantially the same as the planar shape of the ponding recess 134Rb shown in FIGS. 3B and 3C, and a detailed description thereof will be omitted.

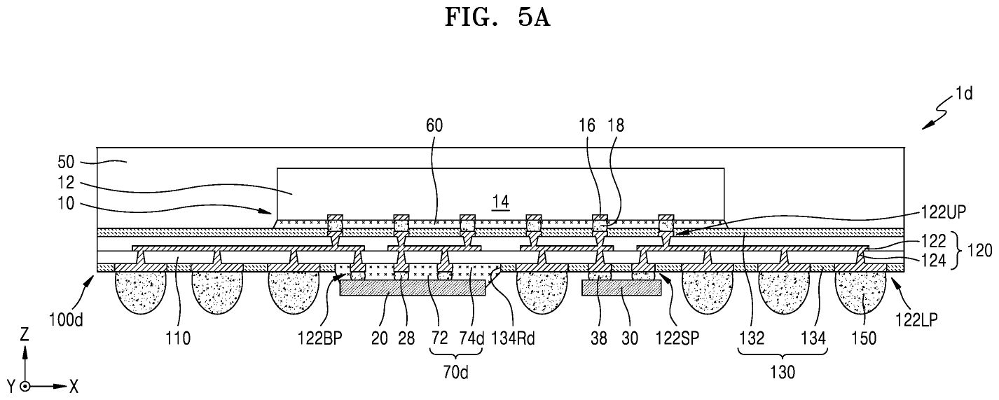

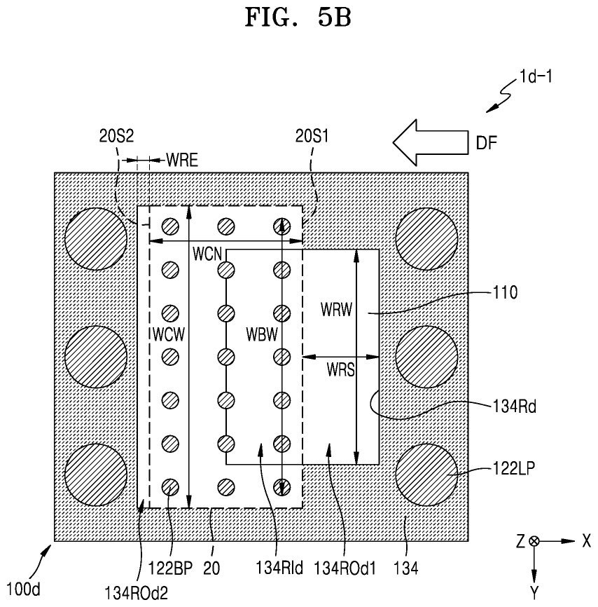

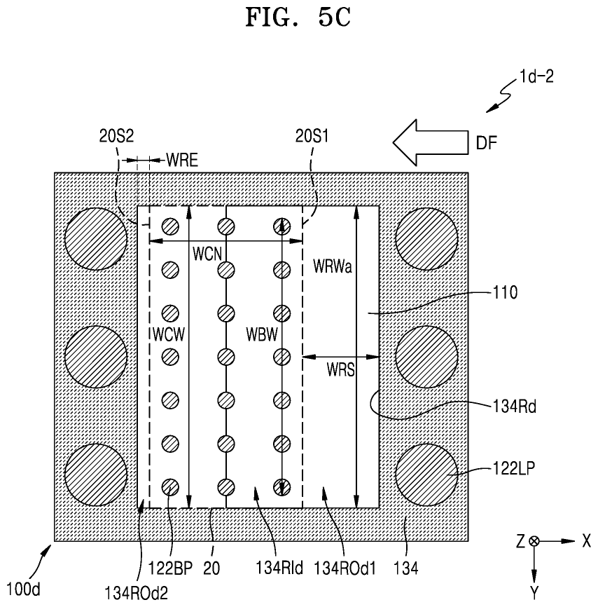

FIG. 5A is a cross-sectional view of a semiconductor package according to an embodiment of the inventive concept, and FIGS. 5B and 5C illustrate the bottom of a package substrate included in a semiconductor package according to an embodiment of the inventive concept. In the descriptions of FIGS. 5A to 5C, descriptions of those components shown in FIGS. 1A to 4 may be omitted.

Referring to FIG. 5A, in some embodiments, a semiconductor package 1d includes a package substrate 100d, a semiconductor chip 10 attached to the upper surface of the package substrate 100d, an auxiliary chip 20 attached to the lower surface of the package substrate 100d, an encapsulant 50 that surrounds the semiconductor chip 10, and an underfill layer 70d that fills a space between the auxiliary chip 20 and the package substrate 100d. In some embodiments, the semiconductor package 1d further includes a unit element chip 30 attached to the lower surface of the package substrate 100d.

In some embodiments, the package substrate 100d is a printed circuit board. The package substrate 100d includes a substrate base 110 and a substrate wiring structure 120. The package substrate 100d further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110. The package substrate 100d includes a ponding recess 134Rd that extends from the lower surface of the lower solder resist layer 134 toward the upper surface thereof. In some embodiments, the ponding recess 134Rd penetrates the lower solder resist layer 134 and exposes the bottom surface of the substrate base 110 on the bottom surface.

The ponding recess 134Rd is formed over the portion of the package substrate 100b adjacent to the auxiliary chip 20 and the portion of the package substrate 100b that overlaps the auxiliary chip 20 in the vertical direction.

The underfill layer 70d fills the ponding recess 134Rd. The underfill layer 70d includes a first underfill portion 72 positioned on the lower side of the lower surface of the lower solder resist layer 134 and that surrounds the plurality of chip terminals 28 and a second underfill portion 74d positioned on the upper side of the lower surface of the lower solder resist layer 134 and that fills the ponding recess 134Rd. The first underfill portion 72 and the second underfill portion 74d are formed together as an integral body.

The first underfill portion 72 covers the upper surface of the auxiliary chip 20 and surrounds the plurality of chip terminals 28. The second underfill portion 74d surrounds a plurality of auxiliary chip connection pads 122BP and fills the ponding recess 134Rd. For example, the first underfill portion 72 covers side surfaces of the plurality of chip terminals 28, and the second underfill portion 74d covers side surfaces of the plurality of auxiliary chip connecting pads 122BP in the ponding recess 134Rd.

The underfill layer 70d fills the space between the auxiliary chip 20 and the package substrate 100d and the ponding recess 134Rd and is formed by injecting resin through the portion of the ponding recess 134Rd that does not overlap the auxiliary chip 20 in the vertical direction.

Referring to FIG. 5B, in some embodiments, the semiconductor package 1d-1 includes a package substrate 100d. The semiconductor package 1d-1 may be the semiconductor package 1d shown in FIG. 5A.

The package substrate 100d includes a lower solder resist layer 134 that covers a portion of the lower surface of the substrate base 110. The auxiliary chip 20 attached to the lower surface of the package substrate 100d includes a first side 20S1 and a second side 20S2 opposite to each other in a planar area in an X-Y plane. The package substrate 100d includes a ponding recess 134Rd that extends from the lower surface of the lower solder resist layer 134 toward the upper surface thereof. The ponding recess 134Rd penetrates the lower solder resist layer 134 and exposes the bottom surface of the substrate base 110.

A part of the ponding recess 134Rd overlaps the auxiliary chip 20 in the vertical direction, and the other part does not overlap the auxiliary chip 20. In the X-Y plane, the ponding recess 134Rd extends from outside of the auxiliary chip 20 to cover the inside of the auxiliary chip 20. For example, the ponding recess 134Rd extends from outside of the auxiliary chip 20 across the first side 20S1 to the second side 20S2 of the auxiliary chip 20 and covers the inside of the auxiliary chip 20.

The ponding recess 134Rd includes an inner recess part 134RId that overlaps the auxiliary chip 20 in the vertical direction, and a first outer recess part 134ROd1 and a second outer recess part 134ROd2 that do not overlap the auxiliary chip 20. The first outer recess part 134ROd1 is connected to the inner recess part 134RId, and the second outer recess part 134ROd2 is connected with the inner recess part 134RId. In some embodiments, in the X-Y plane, the first outer recess part 134ROd1 formed outside of the auxiliary chip 20 on one side of the first side 2051 of the auxiliary chip 20, the second outer recess part 134ROd2 is formed outside of the auxiliary chip 20 on an opposite side of the second side 20S2 of the auxiliary chip 20, and the inner recess part 134RId is formed over the auxiliary chip 20 between each of the first side 20S1 and the second side 20S2 of the auxiliary chip 20.

The auxiliary chip 20 has a first width WCN in the injection direction DF and a second width WCW in a direction perpendicular to the injection direction DF. In some embodiments, the second width WCW is greater than the first width WCN. The first outer recess part 134ROd1 of the ponding recess 134Rd has a third width WRS in the injection direction DF, and a fourth width WRW in a direction perpendicular to the injection direction DF. A column formed by the plurality of auxiliary chip connection pads 122BP in a direction perpendicular to the injection direction DF has a fifth width WBW. The second outer recess part 134ROd2 has a sixth width WRE in the injection direction DF. In some embodiments, the second outer recess part 134ROd2 has a second width WCW in a direction perpendicular to the injection direction DF, but embodiments are not necessarily limited thereto. The third width WRS is equal to or greater than ⅓ of the first width WCN, and the fourth width WRW is greater than or equal to ½ of the second width WCW. In some embodiments, the fourth width WRW is less than the second width WCW. The sixth width WRE is less than the third width WRS. For example, the ponding recess 134Rd is asymmetrically placed with respect to the auxiliary chip 20 in the X-Y plane. The third width WRS is about twice or more than a pitch at which the plurality of auxiliary chip connecting pads 122BP are arranged. The sixth width WRE is about half or less than a pitch at which the plurality of auxiliary chip connection pads 122BP are placed.

Referring to FIG. 5C, in some embodiments, the semiconductor package 1d-2 includes a package substrate 100d. The semiconductor package 1d-2 may be the semiconductor package 1d shown in FIG. 5A.

The ponding recess 134Rd includes the inner recess part 134RId that overlaps an auxiliary chip 20 in the vertical direction, and a first outer recess part 134ROd1 and a second outer recess part 134ROd2 that do not overlap the auxiliary chip 20.

The auxiliary chip 20 has a first width WCN in the injection direction DF and a second width WCW in a direction perpendicular to the injection direction DF. In some embodiments, the second width WCW is greater than the first width WCN. The first outer recess part 134ROd1 of the ponding recess 134Rd has a third width WRS in the injection direction DF, and a fourth width WRWa in a direction perpendicular to the injection direction DF. A column formed by the plurality of auxiliary chip connection pads 122BP in a direction perpendicular to the injection direction DF has a fifth width WBW. The second outer recess part 134ROd2 has a sixth width WRE in the injection direction DF. In some embodiments, the second outer recess part 134ROd2 has a second width WCW in a direction perpendicular to the injection direction DF, but embodiments are not necessarily limited thereto. The fifth width WBW is less than the second width WCW. The third width WRS is equal to or greater than ⅓ of the first width WCN, and the fourth width WRWa is greater than or equal to ½ of the second width WCW. In some embodiments, the fourth width WRWa is equal to the second width WCW. The fourth width WRWa is greater than the fifth width WBW. The sixth width WRE is less than the third width WRS. For example, the ponding recess 134Rd is asymmetrically placed with respect to the auxiliary chip 20 in the X-Y plane.

FIGS. 5A to 5C show the ponding recess 134Rd as penetrating the lower solder resist layer 134 and exposing the bottom surface of the substrate base 110, but embodiments of the inventive concept are not necessarily limited thereto. For example, similar to the ponding recess 134Ra shown in FIGS. 2A to 2C or the ponding recess 134Rc shown in FIG. 4, the ponding recess 134Rd does not extend from the lower surface to the upper surface of the lower solder resist layer 134, so that the lower surface of the substrate base 110 is not exposed and a portion of the lower solder resist layer 134 is exposed.

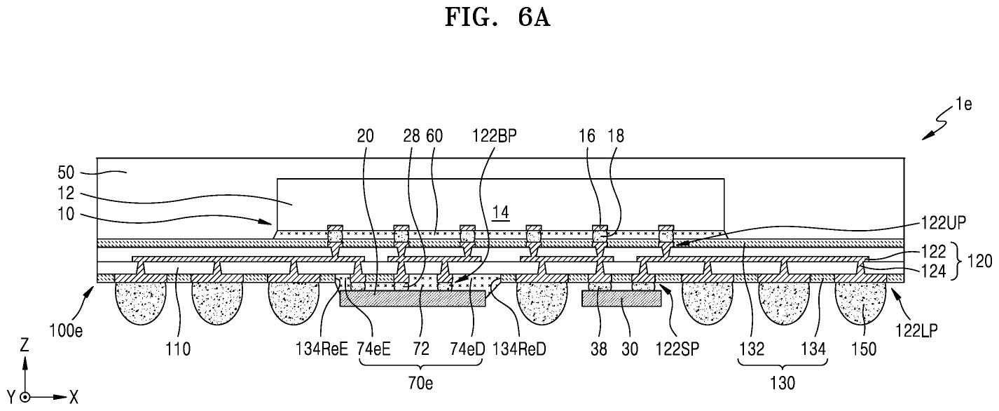

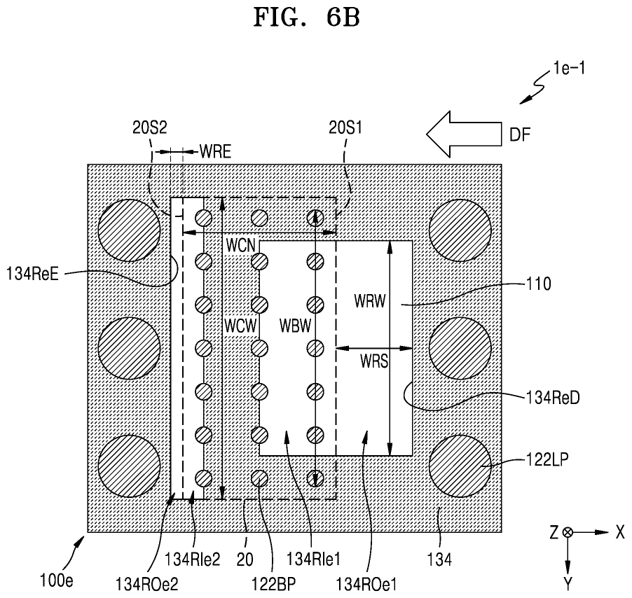

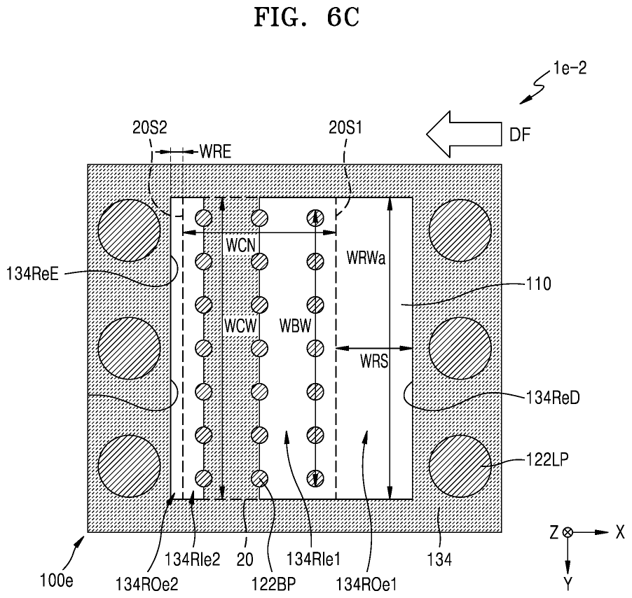

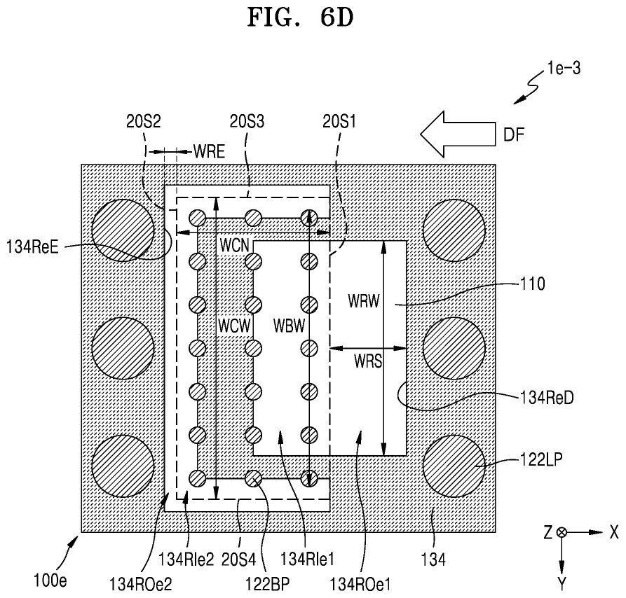

FIG. 6A is a cross-sectional view of a semiconductor package according to an embodiment of the inventive concept, and FIGS. 6B to 6D illustrate the bottom of a package substrate in a semiconductor package according to an embodiment of the inventive concept. In the descriptions of FIGS. 6A to 6D, repeated descriptions of components shown in FIGS. 1A to 5C may be omitted.

Referring to FIG. 6A, in some embodiments, a semiconductor package 1e includes a package substrate 100e, a semiconductor chip 10 attached to the upper surface of the package substrate 100e, an auxiliary chip 20 attached to the lower surface of the package substrate 100e, an encapsulant 50 that surrounds the semiconductor chip 10, and an underfill layer 70e that fills a space between the auxiliary chip 20 and the package substrate 100e. In some embodiments, the semiconductor package 1e further includes a unit element chip 30 attached to the lower surface of the package substrate 100e.

In some embodiments, the package substrate 100e is a printed circuit board. The package substrate 100e includes a substrate base 110 and a substrate wiring structure 120. The package substrate 100e further includes a solder resist layer 130 that covers the upper and lower surfaces of the substrate base 110. The solder resist layer 130 includes an upper solder resist layer 132 that covers the upper surface of the substrate base 110 and a lower solder resist layer 134 that covers the lower surface of the substrate base 110. The package substrate 100e includes a first ponding recess 134ReD and a second ponding recess 134ReE that extend from the lower surface of the lower solder resist layer 134 toward the upper surface and that are spaced apart from each other. In some embodiments, each of the first ponding recess 134ReD and the second ponding recess 134ReE penetrate the lower solder resist layer 134 to expose the bottom surface of the substrate base 110. The first ponding recess 134ReD and the second ponding recess 134ReE are not connected to each other and are spaced apart from each other.

Each of the first ponding recess 134ReD and the second ponding recess 134ReE extends from the portion of the package substrate 100 adjacent to the auxiliary chip 20 to the portion of the package substrate 100 that overlaps the auxiliary chip 20 in the vertical direction, such that a portion of the auxiliary chip 20 overlaps in the vertical direction a portion of the first ponding recess 134ReD and a portion of the second ponding recess 134ReE.

The underfill layer 70e fills each of the first ponding recess 134ReD and the second ponding recess 134ReE. The underfill layer 70d includes a first underfill portion 72 located below lower surface of the lower solder resist layer 134 and that surrounds the plurality of chip terminals 28, a second underfill portion 74eD located above the lower surface of the lower solder resist layer 134 and that fills the first ponding recess 134ReD, and a third underfill portion 74eE located above the lower surface of the lower solder resist layer 134 and that fills the second ponding recess 134ReE. The first underfill portion 72, the second underfill portion 74eD, and the third underfill portion 74eE are formed together as an integral body.

The underfill layer 70e fills the space between the auxiliary chip 20 and the package substrate 100d, the first ponding recess 134ReD and the second ponding recess 134ReE, and is formed by injecting resin through the portion of the first ponding recess 134ReD that does not overlap the auxiliary chip 20 in the vertical direction.

Referring to FIG. 6B, in some embodiments, the semiconductor package 1e-1 includes a package substrate 100e. The semiconductor package 1e-1 may be the semiconductor package 1e shown in FIG. 6A.

The first ponding recess 134ReD extends from outside of the auxiliary chip 20 across the first side 20S1 of the auxiliary chip 20 to cover part of the inside of the auxiliary chip 20, and the second ponding recess 134ReE extends from outside of the auxiliary chip 20 across the second side 20S2 of the auxiliary chip 20 to cover part of the inside of the auxiliary chip 20. In some embodiments, the horizontal area of the first ponding recess 134ReD is greater than the horizontal area of the second ponding recess 134ReE.

The first ponding recess 134ReD includes a first inner recess part 134RIe1 that overlaps the auxiliary chip 20 in the vertical direction and a first outer recess part 134ROe1 that does not overlap with the auxiliary chip 20, and the second ponding recess 134ReE includes a second inner recess part 134RIe2 that overlaps the auxiliary chip 20 in the vertical direction and a second outer recess part 134ROe2 that does not overlap with the auxiliary chip 20. In the X-Y plane, the first outer recess part 134ROe1 and the second outer recess part 134ROe2 formed outside of the auxiliary chip 20 on one side of each of the first side 20S1 and the second side 20S2 of the auxiliary chip 20, respectively, and the first inner recess part 134RIe1 and the second inner recess part 134RIe2 formed over the inside the auxiliary chip 20 on the other sides of each of the first side 20S1 and the second side 20S2 of the auxiliary chip 20.

The auxiliary chip 20 has a first width WCN in the injection direction DF and a second width WCW in a direction perpendicular to the injection direction DF. In some embodiments, the second width WCW is greater than the first width WCN. The first outer recess part 134ROe1 has a third width WRS in the injection direction DF, and a fourth width WRW in a direction perpendicular to the injection direction DF. A column formed by the plurality of auxiliary chip connection pads 122BP in a direction perpendicular to the injection direction DF has a fifth width WBW. The second outer recess part 134ROe2 has a sixth width WRE in the injection direction DF. In some embodiments, the second outer recess part 134ROe2 has a second width WCW in a direction perpendicular to the injection direction DF, but embodiments are not necessarily limited thereto. The fifth width WBW is less than the second width WCW. The fifth width WBW is greater than the fourth width WRW. The third width WRS is equal to or greater than ⅓ of the first width WCN, and the fourth width WRW is greater than or equal to ½ of the second width WCW. In some embodiments, the fourth width WRW is less than the second width WCW. The sixth width WRE is less than the third width WRS. For example, the first ponding recess 134Re1 and the second ponding recess 134Re2 are asymmetrically arranged with respect to the auxiliary chip 20 in the X-Y plane.

Referring to FIG. 6C, in some embodiments, the semiconductor package 1e-2 includes a package substrate 100e. The semiconductor package 1e-2 may be the semiconductor package 1e shown in FIG. 6A.

The first ponding recess 134ReD extends from outside of the auxiliary chip 20 across the first side 20S1 of the auxiliary chip 20 to cover the inside of the auxiliary chip 20, and the second ponding recess 134ReE extends from outside of the auxiliary chip 20 across the second side 20S2 of the auxiliary chip 20 to cover the inside of the auxiliary chip 20. In some embodiments, the horizontal area of the first ponding recess 134ReD is greater than the horizontal area of the second ponding recess 134ReE.

The auxiliary chip 20 has a first width WCN in the injection direction DF and a second width WCW in a direction perpendicular to the injection direction DF. In some embodiments, the second width WCW is greater than the first width WCN. The first outer recess part 134ROe1 has a third width WRS in the injection direction DF, and a fourth width WRWa in a direction perpendicular to the injection direction DF. A column formed by the plurality of auxiliary chip connection pads 122BP in a direction perpendicular to the injection direction DF has a fifth width WBW. The second outer recess part 134ROe2 has a sixth width WRE in the injection direction DF. In some embodiments, the second outer recess part 134ROe2 has a second width WCW in a direction perpendicular to the injection direction DF, but embodiments are not necessarily limited thereto. The fifth width WBW is less than the second width WCW. The third width WRS is equal to or greater than ⅓ of the first width WCN, and the fourth width WRWa is greater than or equal to ½ of the second width WCW. In some embodiments, the fourth width WRWa is equal to the second width WCW. The fourth width WRWa is greater than the fifth width WBW. The sixth width WRE is less than the third width WRS. For example, the first ponding recess 134Re1 and the second ponding recess 134Re2 are asymmetrically arranged with respect to the auxiliary chip 20 in the X-Y plane.

FIGS. 6A to 6C show that each of the first ponding recess 134Re1 and the second ponding recess 134Re2 penetrates the lower solder resist layer 134 and exposes the bottom surface of the substrate base 110, but embodiments of the inventive concept are not necessarily limited thereto. For example, similar to the ponding recess 134Ra shown in FIGS. 2A to 2C or the ponding recess 134Rc shown in FIG. 4, each of the first ponding recess 134Re1 and the second ponding recess 134Re2 does not extend from the lower surface to the upper surface of the lower solder resist layer 134, so that the substrate base 110 is not exposed on the lower surface and a portion of the lower solder resist layer 134 is exposed.

Referring to FIG. 6D, in some embodiments, the semiconductor package 1e-3 may include a package substrate 100e. The semiconductor package 1e-3 may be the semiconductor package 1e shown in FIG. 6A.

The auxiliary chip 20 has a first side 20S1 and a second side 20S2 opposite to each other in the X-Y plane, and a third side 20S3 and a fourth side 20S4 that connect the first side 20S1 and the second side S20S2 and are opposite to each other.

The first ponding recess 134ReD extends from outside of the auxiliary chip 20 across the first side 20S1 of the auxiliary chip 20 to cover a portion of the inside of the auxiliary chip 20, and the second ponding recess 134ReE extends from outside of the auxiliary chip 20 across the second side 20S2, the third side 20S3, and the fourth side 20S4 of the auxiliary chip 20 to cover a portion of the inside of the auxiliary chip 20. A portion of the auxiliary chip 20 between the first ponding recess 134ReD and the second ponding recess 134ReE does not overlap the first ponding recess 134ReD and the second ponding recess 134 in the vertical direction.

The second ponding recess 134ReE shown in FIG. 6C has a bar shape that extends along the second side 20S2 of the auxiliary chip 20, and the second ponding recess 134ReE shown in FIG. 6D may have a C-shape or a U-shape that extends along the second side 20S2, the third side 20S3, and the fourth side 20S4 of the auxiliary chip 20.

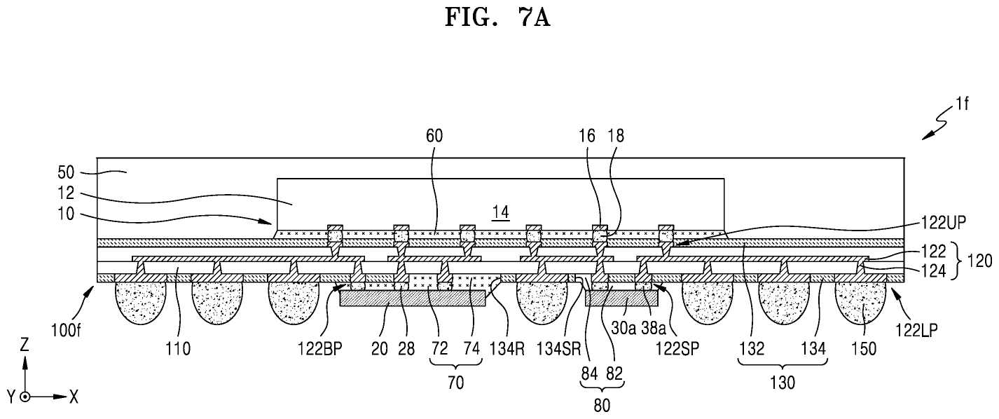

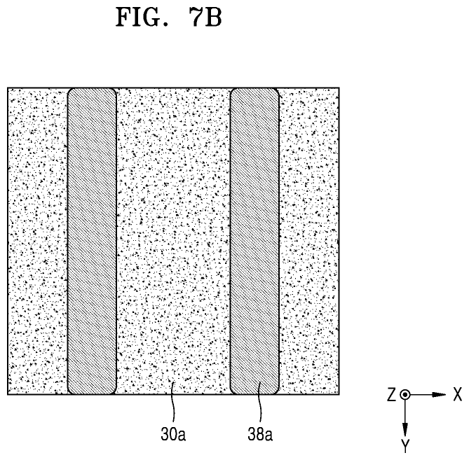

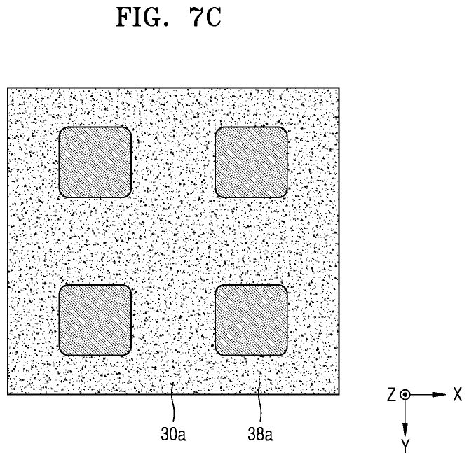

FIG. 7A is a cross-sectional view of a semiconductor package according to an embodiment of the inventive concept, and FIGS. 7B and 7C illustrate the top of a unit element chip in a semiconductor package according to an embodiment of the inventive concept. In the descriptions of FIGS. 7A to 7C, repeated descriptions of those components shown in FIGS. 1A to 1D may be omitted.

Referring to FIG. 7A, in some embodiments, compared to the semiconductor package 1 shown in FIG. 1A, the semiconductor package if further includes a sub underfill layer 80, a package substrate 100f instead of the package substrate 100, and a unit element chip 30a and a plurality of element terminals 38a instead of the unit element chip 30 and the plurality of element terminals 38. The unit element chip 30a may be a passive element or an active element. The package substrate 100f further includes a sub ponding recess 134SR, unlike the package substrate 100 shown in FIG. 1A. In an X-Y plane, the sub ponding recess 134SR is asymmetrically placed with respect to the unit element chip 30a.

In some embodiments, the sub ponding recess 134SR penetrates the lower solder resist layer 134 and exposes the bottom surface of the substrate base 110. The sub ponding recess 134SR is formed by removing a portion of the lower solder resist layer 134. In some embodiments, at least some of the plurality of element connection pads 122SP are placed in the sub ponding recess 134SR. The side surface of the element connection pad 122SP are exposed by not being covered by the lower solder resist layer 134.

In some embodiments, the unit element chip 30a is attached to the lower surface of the package substrate 100f so that at least a portion thereof overlaps the sub ponding recess 134SR in the vertical direction. For example, the sub ponding recess 134R extends from a portion of the package substrate 100f adjacent to the unit element chip 30a to a portion of the package substrate 100f that overlaps the unit element chip 30a in the vertical direction, so that a portion of the unit element chip 30a and a portion of the sub ponding recess 134SR overlap in the vertical direction. In some embodiments, the sub ponding recess 134SR is formed in a portion of the package substrate 100f adjacent to the unit element chip 30a, or the sub ponding recess 134SR is formed over the entire portion of the package substrate 100f that overlaps the unit element chip 30a in the vertical direction.

The sub underfill layer 80 includes a first sub underfill portion 82 that surrounds the plurality of element terminals 38a and a second sub underfill portion 84 that fills the sub ponding recess 134SR.

The sub underfill layer 80 that fills the space between the unit element chip 30a and the package substrate 100f and the sub ponding recess 134SR shown in FIG. 7A have a shape similar to that of the underfill layer 70 that fills the space between the auxiliary chip 20 and the package substrate 100 and the ponding recess 134R shown in FIGS. 1A, but embodiments of the inventive concept are not necessarily limited thereto. For example, in some embodiments, the sub underfill layer 80 and the sub ponding recess 134SR have a shape similar to that of the underfill layers 70a, 70b, 70c, 70d, and 70e of the semiconductor packages 1a, 1a-1, 1a-2, 1b, 1b-1, 1b-2, 1c, 1d, 1d-1, 1d-2, 1e, 1e-1, and 1e and the ponding recesses 134Ra, 134Rb, 134Rc, and 134Rd or the first ponding recess 134ReD and the second ponding recess 134ReE of the package substrates 100a, 100b, 100c, 100d, and 100e, respectively, described with reference to FIGS. 2A to 6D. referring to the underfill layers 70a, 70b, 70c, 70d, and 70e of the semiconductor packages 1a, 1a-1, 1a-2, 1b, 1b-1, 1b-2, 1c, 1d, 1d-1, 1d-2, 1e, 1e-1, and 1e and the ponding recesses 134Ra, 134Rb, 134Rc, and 134Rd or the first ponding recess 134ReD and the second ponding recess 134ReE of the package substrates 100a, 100b, 100c, 100d, and 100e, respectively, described with reference to FIGS. 2A to 6D, it is easy for those skilled in the art to modify the sub underfill layer 80 included in the semiconductor package 1f and the sub ponding recess 134SR of the package substrate 100f shown in FIG. 7A, so that a detailed description will be omitted.

Referring to FIGS. 7A and 7B together, in some embodiments, the semiconductor package if further includes a unit element chip 30a attached to the lower surface of the package substrate 100f. The unit element chip 30a is spaced apart from the auxiliary chip 20.

The unit element chip 30a is connected to a plurality of element connection pads 122SP of the package substrate 100f through a plurality of element terminals 38a. For example, the unit element chip 30a includes two element terminals 38a.

In some embodiments, the sum of the horizontal areas of the plurality of element terminals 38a in the X-Y plane is less than ⅓ of the horizontal area of the unit element chip 30a.

Referring to FIGS. 7A and 7C together, in some embodiments, the semiconductor package if further includes a unit element chip 30a attached to the lower surface of the package substrate 100f.

The unit element chip 30a is connected to a plurality of element connection pads 122SP of the package substrate 100f through a plurality of element terminals 38a. For example, the unit element chip 30a includes four or more element terminals 38a.

Because the semiconductor package if according to some embodiments of the inventive concept includes a sub underfill layer 80, and the package substrate 100f has a sub ponding recess 134SR, the bonding strength of a plurality of element terminals 38a and the package substrate 100f, and the bonding strength of the plurality of element terminals 38a and the unit element chip 30 is increased, and the reliability of electrical connection between the package substrate 100f and the unit element chip 30a through a plurality of element terminals 38a is secured.

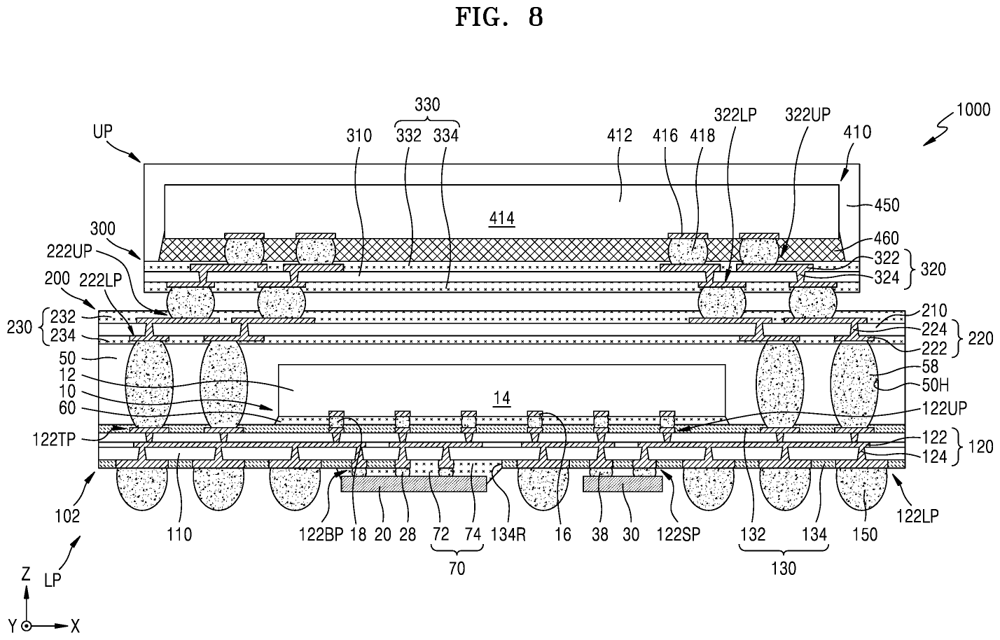

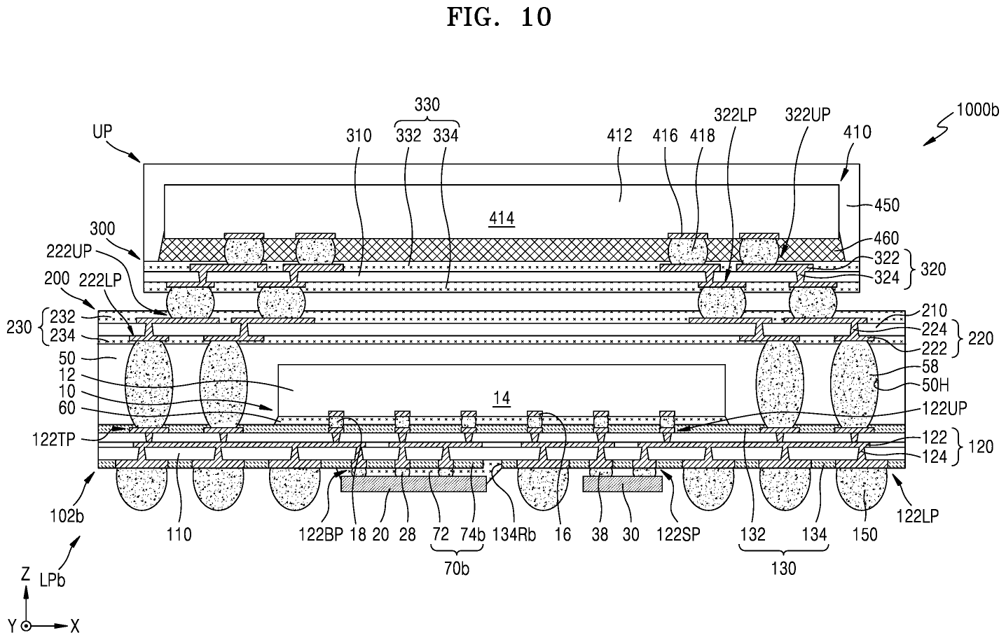

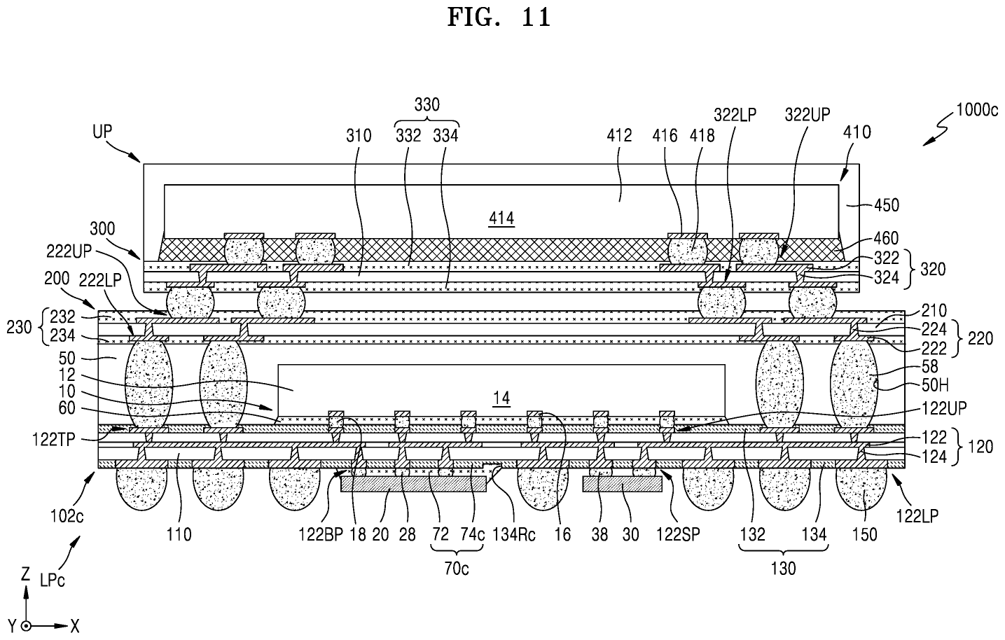

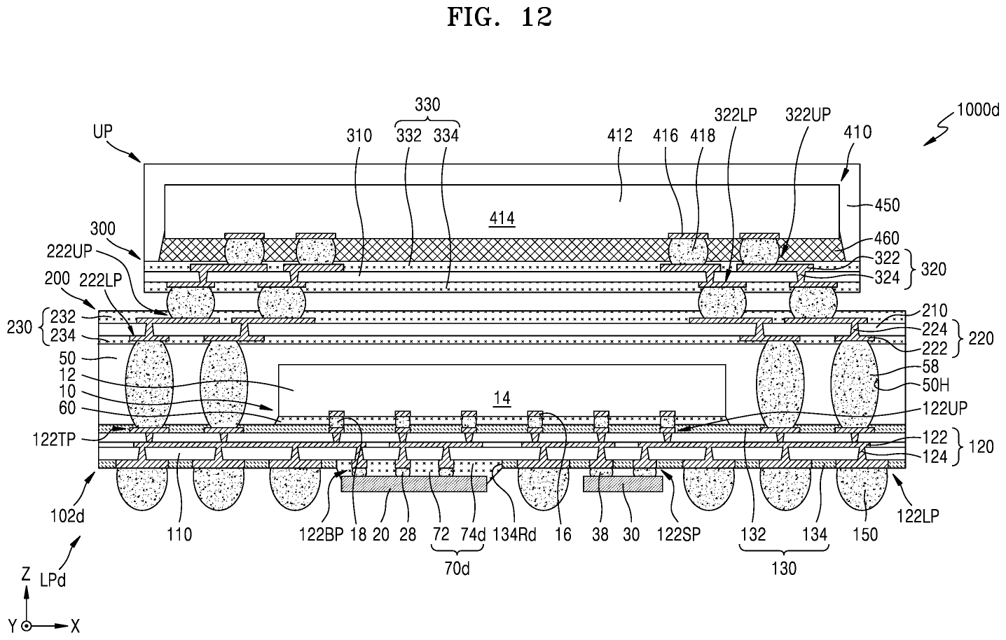

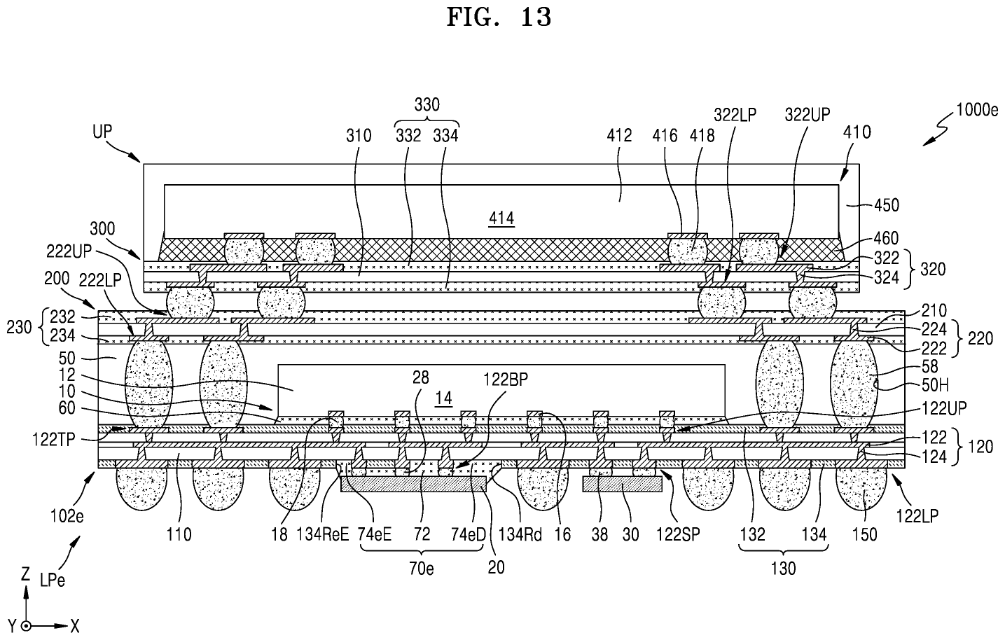

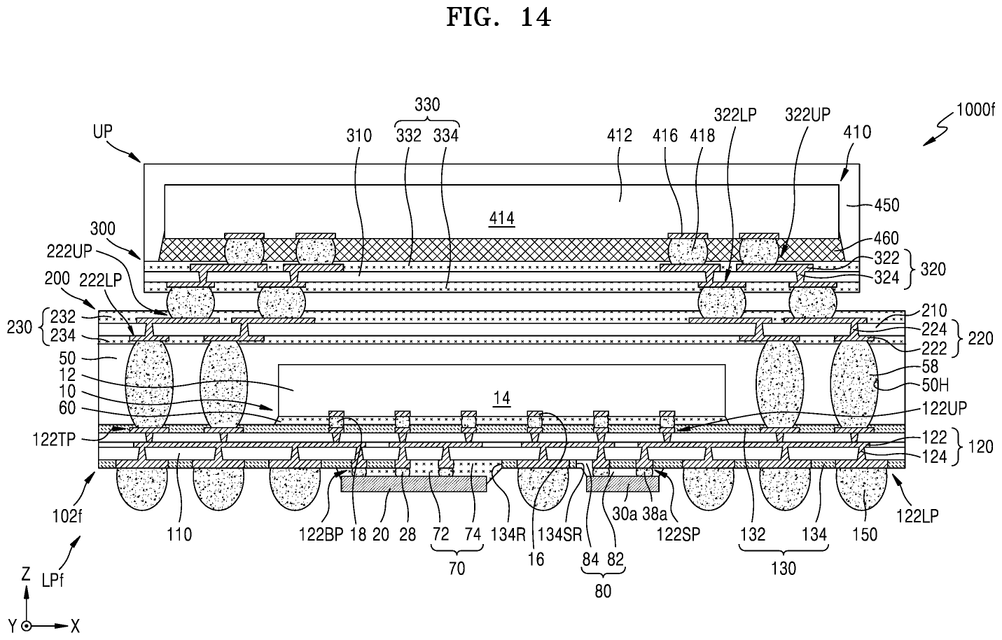

FIGS. 8 to 14 are cross-sectional views of a package on package (PoP) type semiconductor package according to an embodiment of the inventive concept. In the descriptions of FIGS. 8 to 14, repeated descriptions of those components shown FIGS. 1 to 7C may be omitted.

Referring to FIG. 8, in an embodiment, the semiconductor package 1000 is a PoP type semiconductor package in which an upper package UP is attached to a lower package LP.

The lower package LP includes a second package substrate 102, a lower semiconductor chip 10 attached to the upper surface of the first package substrate 102, an auxiliary chip 20 attached to the lower surface of the first package substrate 102, an encapsulant 50 that surrounds the lower semiconductor chip 10, a second package substrate 200 that covers the encapsulant 50, and an underfill layer 70 that fills a space between the auxiliary chip 20 and the package substrate 100.

A component in the lower package LP that has the same reference number as a component in the semiconductor package 1 shown in FIG. 1A is the same component, and the lower semiconductor chip 10 is the semiconductor chip 10 shown in FIG. 1A, and the first package substrate 102 is similar to the package substrate 100 shown in FIG. 1A, and repeated descriptions thereof may be omitted.

The first package substrate 102 includes a first substrate base 110, a first substrate wiring structure 120 that includes a plurality of first wiring patterns 122 and a plurality of first wiring vias 124, and a first solder resist layer 130 that includes a first upper solder resist layer 132 and a first lower solder resist layer 134. The first substrate base 110, the first substrate wiring structure 120, the first wiring pattern 122, the first wiring via 124, the first solder resist layer 130, the first upper solder resist layer 132, and the first lower solder resist layer 134 in the first package substrate 102 are substantially the same as the first substrate base 110, the first substrate wiring structure 120, the wiring pattern 122, the wiring via 124, the solder resist layer 130, the upper solder resist layer 132, and the lower solder resist in the package substrate 100 shown in FIG. 1A.

Some of the first wiring patterns 122 on the upper surface of the first substrate base 110 that are exposed by not being covered by the first upper solder resist layer 132 are referred to as a plurality of first upper chip connection pads 122UP and a plurality of first upper connection pads 122TP. Some of the first wiring patterns 122 on the lower surface of the first substrate base 110 that are exposed by not being covered by the first lower solder resist layer 134 are referred to as a plurality of first lower connection pads 122LP and a plurality of auxiliary chip connection pads 122BP. A plurality of external connection terminals 150 are attached to the plurality of first lower connection pads 122LP.

The second package substrate 200 includes a second substrate base 210, a second substrate wiring structure 220 that includes a plurality of first wiring patterns 222 and a plurality of first wiring vias 224, and a first solder resist layer 230 that includes a first upper solder resist layer 232 and a first lower solder resist layer 234. Some second wiring patterns 222 on the upper surface of the second substrate base 210 that are exposed by not being covered by the second upper solder resist layer 232 are referred to as a plurality of second upper chip connection pads 222UP, and some second wiring patterns 222 on the lower surface of the second substrate base 210 that are exposed by not being covered by the second lower solder resist layer 234 are referred to as a plurality of second lower connection pads 222LP. The second package substrate 200 is substantially similar to the first package substrate 102, and a repeated description thereof is omitted.

The encapsulant 50 is substantially similar to the encapsulant 50 shown in FIG. 1A, but include a plurality of through via holes 50H that extending from the upper surface to the lower surface of the encapsulant 50. A plurality of through connection members 58 are respectively disposed in the plurality of through via holes 50H. The plurality of through connection members 58 electrically connect the plurality of second lower connection pads 222LP and the plurality of first upper connection pads 122TP.

The upper package UP includes a third package substrate 300, an upper semiconductor chip 410 attached to the upper surface of the third package substrate 300, and an upper molding member 450 that surrounds the upper semiconductor chip 410.

The third package substrate 300 includes a third substrate base 310, a third substrate wiring structure 320 that includes a plurality of third wiring patterns 322 and a plurality of third wiring vias 324, and a third solder resist layer 330 that includes a third upper solder resist layer 332 and a third lower solder resist layer 334. Some of the third wiring patterns 322 on the upper surface of the third substrate base 310 are exposed by not being covered by the third upper solder resist layer 332 and are referred to as a plurality of third upper chip connection pads 322UP. Some of the third wiring patterns 322 on the lower surface of the third substrate base 310 are exposed by not being covered by the third lower solder resist layer 334 and are referred to as a plurality of third lower connection pads 322LP. The third package substrate 300 is substantially similar to the second package substrate 200, and a repeated description thereof is omitted.

The upper semiconductor chip 410 includes an upper semiconductor substrate 412 that includes an active surface and an inactive surface opposite to each other, an upper semiconductor element 414 formed on the active surface of the upper semiconductor substrate 412, and a plurality of upper chip pads 416 placed on the first surface of the upper semiconductor chip 410. The upper semiconductor chip 410 and the third package substrate 300 are electrically connected through a plurality of upper chip connection members 418 that connect the plurality of upper chip pads 416 and the plurality of third substrate upper surface pads 322 to each other. Since the upper semiconductor chip 410 is substantially similar to the lower semiconductor chip 10, a repeated description thereof is omitted.

In some embodiments, the lower semiconductor chip 10 may be a CPU chip, a GPU chip, or an AP chip, and the upper semiconductor chip 410 may be a memory semiconductor chip.

In some embodiments, an upper underfill layer 460 that surrounds the plurality of upper chip connection members 418 is formed between the second surface, for example, the lower surface, of the upper semiconductor chip 410 and the third package substrate 300. In some embodiments, the upper molding member 450 covers the upper surface of the third package substrate 300 and surrounds the upper semiconductor chip 410 and the upper underfill layer 460.

FIG. 8 shows that the upper semiconductor chip 410 has a face-up arrangement and is attached to the upper surface of the third package substrate 300, but embodiments of the inventive concept are not necessarily limited thereto. For example, in some embodiments, the upper semiconductor chip 410 has a face-down arrangement and is attached to the upper surface of the third package substrate 300.

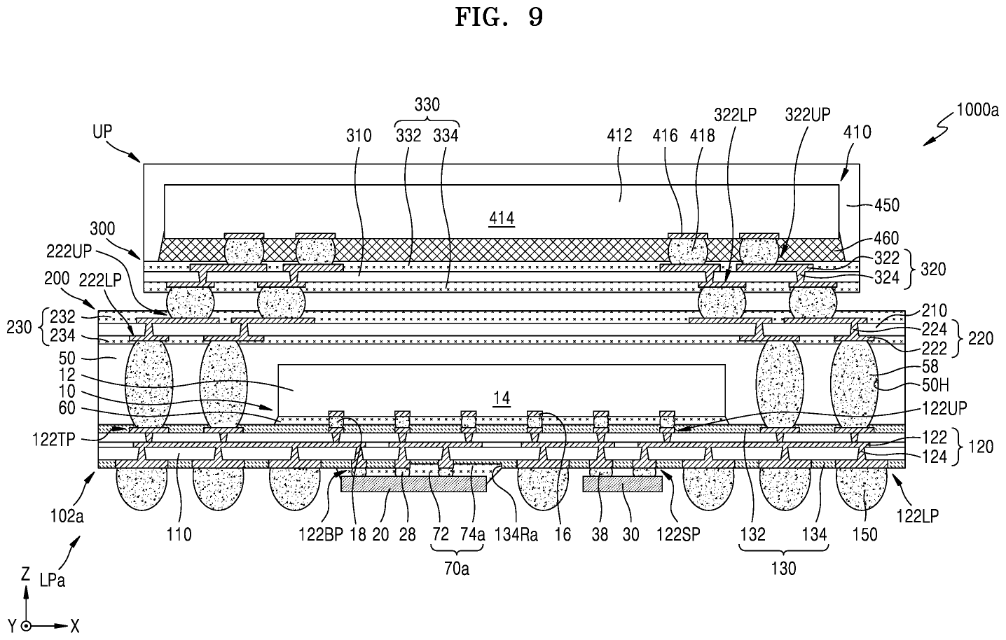

Referring to FIGS. 9 to 14 together, in some embodiments, the semiconductor packages 1000a, 1000b, 1000c, 1000d, 1000e, and 1000f are PoP type semiconductor packages in which the upper package UP is attached on the lower packages LPa, LPb, LPc, LPd, LPe, and LPf.

As the lower package LP and the first package substrate 102 in the lower package LP shown in FIG. 8 is configured similarly to the semiconductor package 1 and the package substrate 100 in the semiconductor package 1 shown in FIG. 1A, the lower packages LPa, LPb, LPc, LPd, LPe, and LPf and the first package substrate 102a, 102b, 102c, 102d, 102e, 102f in the lower packages LPa, LPb, LPc, LPd, LPe, and LPf are configured similarly to the semiconductor packages 1a, 1b, 1c, 1d, 1e, and if and the package substrate 100a, 100b, 100c, 100d, 100e, and 100f in the semiconductor packages 1a, 1b, 1c, 1d, 1e, and if shown in FIGS. 2A to 7C, and repeated detailed descriptions thereof are omitted.

While embodiments of the inventive concept have been particularly shown and described with reference to drawings thereof, it will be understood that various changes in form and details may be made therein without departing from the spirit and scope of the following claims.

What is claimed is:

1. A semiconductor package, comprising:
a package substrate that includes a substrate base and a lower solder resist layer that covers a lower surface of the substrate base, wherein the lower solder resist layer includes a ponding recess that extends from a lower surface toward an upper surface of the lower solder resist layer;
a semiconductor chip attached to an upper surface of the package substrate;
an auxiliary chip attached to a lower surface of the package substrate adjacent to the ponding recess through a plurality of chip terminals, wherein the auxiliary chip includes a first side and a second side opposite to each other in a plane; and
an underfill layer that fills a space between the package substrate and the auxiliary chip, surrounds the plurality of chip terminals, and fills the ponding recess,
wherein the ponding recess is arranged asymmetrically with respect to the auxiliary chip in a plane.

2. The semiconductor package of claim 1, wherein the ponding recess extends from the lower surface of the lower solder resist layer to the upper surface of the lower solder resist layer and penetrates the lower solder resist layer.

3. The semiconductor package of claim 1, wherein the ponding recess extends from the lower surface of the lower solder resist layer toward the upper surface of the lower solder resist layer, but does not penetrate the lower solder resist layer.

4. The semiconductor package of claim 1, wherein, in a first horizontal direction perpendicular to the first side of the auxiliary chip, the auxiliary chip has a first width, a portion of the ponding recess that does not overlap the auxiliary chip in a vertical direction has a second width, and the second width is equal to or greater than ⅓ of the first width.

5. The semiconductor package of claim 1, wherein the ponding recess extends from outside of the auxiliary chip across the first side of the auxiliary chip in a plane to cover an inside of the auxiliary chip, and comprises an inner recess part that overlaps the auxiliary chip in a vertical direction and an outer recess part connected to the inner recess part and that does not overlap the auxiliary chip.

6. The semiconductor package of claim 1, wherein the ponding recess extends from outside of the auxiliary chip across the first side and the second side of the auxiliary chip in a plane to cover the inside of the auxiliary chip.

7. The semiconductor package of claim 6, wherein the ponding recess comprises an inner recess part that overlaps the auxiliary chip in a vertical direction, a first outer recess part connected to the inner recess part and placed outside a first sidewall of the auxiliary chip and that does not overlap the auxiliary chip, and a second outer recess part connected to the inner recess part and placed outside a second sidewall of the auxiliary chip and that does not overlap the auxiliary chip,
wherein, in a first horizontal direction perpendicular to the first side of the auxiliary chip, a width of the first outer recess part is greater than a width of the second outer recess part.

8. The semiconductor package of claim 7, wherein, in a second horizontal direction perpendicular to the first horizontal direction, a width of the second outer recess part is greater than a width of the first outer recess part.

9. The semiconductor package of claim 6, wherein the ponding recess comprises a first ponding recess that extends from outside of the auxiliary chip across the first side of the auxiliary chip in a plane to cover the inside of the auxiliary chip, and a second ponding recess that is spaced apart from the first ponding recess and that extends from outside of the auxiliary chip across the second side of the auxiliary chip to cover the inside of the auxiliary chip.

10. The semiconductor package of claim 9,
wherein the first ponding recess comprises a first inner recess part that overlaps the auxiliary chip in a vertical direction, and a first outer recess part connected to the first inner recess part and placed outside of a first sidewall of the auxiliary chip and that does not overlap the auxiliary chip,
wherein the second ponding recess comprises a second inner recess part that overlaps the auxiliary chip in the vertical direction and is spaced apart from the first inner recess part, and a second outer recess part connected to the second inner recess part and placed outside of a second sidewall of the auxiliary chip and that does not overlap the auxiliary chip,
wherein, a width of the first outer recess part in a first horizontal direction is greater than a width of the second outer recess part.

11. A semiconductor package, comprising:
a package substrate that includes a substrate base, a plurality of upper chip connection pads placed on an upper surface of the substrate base, a plurality of lower connection pads and a plurality of auxiliary chip connection pads placed on a lower surface of the substrate base, and a lower solder resist layer that covers the lower surface of the substrate base and does not cover the plurality of lower connection pads and the plurality of auxiliary chip connection pads, wherein the lower solder resist layer includes a ponding recess that extends from a lower surface of the lower solder resist layer toward an upper surface of the lower solder resist layer;
a plurality of chip connection members respectively attached to the plurality of upper chip connection pads;
a main semiconductor chip attached to the plurality of chip connection members;
an auxiliary chip attached to a lower surface of the package substrate and adjacent to the ponding recess through a plurality of chip terminals attached to the plurality of auxiliary chip connection pads, wherein the auxiliary chip includes first and second sides opposite to each other in a plane;
a plurality of external connection terminals attached to the plurality of lower connection pads; and
an underfill layer that fills a space between the package substrate and the auxiliary chip, surrounds the plurality of chip terminals, and fills the ponding recess,
wherein the ponding recess is arranged asymmetrically with respect to the auxiliary chip in a first horizontal direction perpendicular to a first side of the auxiliary chip.

12. The semiconductor package of claim 11, wherein, in the ponding recess, a horizontal width in the first horizontal direction of a portion outside of a first sidewall of the auxiliary chip and that does not overlap the auxiliary chip is at least twice a pitch at which the plurality of auxiliary chip connection pads are arranged.

13. The semiconductor package of claim 11, wherein, in the ponding recess, a horizontal width in the first horizontal direction of a portion outside of a first sidewall of the auxiliary chip and that does not overlap the auxiliary chip is greater than a horizontal width in the first horizontal direction of a portion outside of a second sidewall of the auxiliary chip and that does not overlap the auxiliary chip.

14. The semiconductor package of claim 11, wherein the underfill layer comprises a first underfill portion positioned below the lower surface of the lower solder resist layer and that surrounds the plurality of chip terminals, and a second underfill portion that forms an integral body with the first underfill portion and fills the ponding recess,
wherein a first height of the first underfill portion is less than a second height of the second underfill portion.

15. The semiconductor package of claim 14,
wherein at least some of the plurality of auxiliary chip connecting pads are placed in the ponding recess, and
wherein the second underfill portion covers side surfaces of at least some of the plurality of auxiliary chip connection pads in the ponding recess.

16. The semiconductor package of claim 11, wherein, in the ponding recess, a width of a portion outside a first sidewall of the auxiliary chip in a second horizontal direction perpendicular to the first horizontal direction and that does not overlap the auxiliary chip is less than a width of the auxiliary chip.

17. The semiconductor package of claim 11,
wherein the package substrate further comprises a plurality of element connection pads placed on the lower surface of the substrate base and that are not covered by the lower solder resist layer,
wherein the lower solder resist layer further includes a sub ponding recess that is spaced apart from the ponding recess and extends from the lower surface of the lower solder resist layer toward the upper surface of the lower solder resist layer,
wherein the semiconductor package further comprises:
a unit element chip adjacent to the sub ponding recess and connected to the plurality of element connection pads through a plurality of element terminals; and
a sub underfill layer that fills a space between the package substrate and the unit element chip, surrounds the plurality of element terminals, and fills the sub ponding recess,
wherein the plurality of element terminals include four or more element terminals, or a sum of horizontal areas of the plurality of element terminals is less than ⅓ of a horizontal area of the unit element chip,
wherein, in a plane, the sub ponding recess is asymmetrically arranged with respect to the unit element chip.

18. A semiconductor package, comprising:
a package substrate that includes a substrate base, a plurality of upper chip connection pads placed on an upper surface of the substrate base, a plurality of lower connection pads and a plurality of auxiliary chip connection pads placed on a lower surface of the substrate base, and a lower solder resist layer that covers the lower surface of the substrate base and does not cover the plurality of lower connection pads and the plurality of auxiliary chip connection pads, wherein the lower solder resist layer includes a ponding recess that extends from a lower surface toward an upper surface of the lower solder resist layer;
a plurality of chip connection members attached to the plurality of upper chip connection pads;
a main semiconductor chip attached to the plurality of chip connection members;
an encapsulant that surrounds the main semiconductor chip on the upper surface of the package substrate;
an auxiliary chip attached to a lower surface of the package substrate adjacent to the ponding recess through a plurality of chip terminals attached to the plurality of auxiliary chip connection pads, wherein the auxiliary chip includes first and second sides opposite to each other in a plane;
a plurality of external connection terminals attached to the plurality of lower connection pads; and
an underfill layer that fills a space between the package substrate and the auxiliary chip, surrounds the plurality of chip terminals, and fills the ponding recess,
wherein the ponding recess is arranged asymmetrically with respect to the auxiliary chip in a first horizontal direction perpendicular to a first side of the auxiliary chip,
wherein a depth of the ponding recess is greater than a height of each of the plurality of chip connection members.

19. The semiconductor package of claim 18, wherein the height of each of the plurality of chip connection members is from about 3 μm to about 15 μm.

20. The semiconductor package of claim 18, wherein a thickness of the lower solder resist layer is greater than the height of each of the plurality of chip connection members, wherein the thickness is from about 5 μm to about 20 μm.
